(19) United States
(12) Patent Application Publication
(10) Pub. No.: US 2026/0173527 A1
(43) Pub. Date: Jun. 18, 2026

(54) DRIVING CIRCUIT STRUCTURE, ARRAY SUBSTRATE, DISPLAY DEVICE, METHOD OF PREPARING THE ARRAY SUBSTRATE

(71) Applicants: Wuhan BOE Optoelectronics Technology Co., Ltd., Wuhan, Hubei (CN); BOE Technology Group Co., Ltd., Beijing (CN)

(72) Inventors: Zengjie KONG, Beijing (CN); Yujie GAO, Beijing (CN); Peng JIANG, Beijing (CN); Xin LIU, Beijing (CN); Lu SHEN, Beijing (CN); Junling HUANG, Beijing (CN); Chenguang GUO, Beijing (CN); Chao WANG, Beijing (CN); Dan LI, Beijing (CN)

(21) Appl. No.: 18/709,998

(22) PCT Filed: Aug. 31, 2023
(86) PCT No.: PCT/CN2023/116040

§ 371 Date: May 14, 2024

(51) Int. Cl. H10D 86/40; H10D 86/01

(52) U.S. Cl. CPC H10D 86/441; H10D 86/0231

(57) ABSTRACT

A driving circuit structure, an array substrate, a display device, and a method for preparing the array substrate are provided. The driving circuit structure includes: a base substrate; an initial signal line on the base substrate; a clock signal line on the base substrate; and a first insulating layer on a side of the initial signal line away from the base substrate and including a first via. The initial signal line is connected to the clock signal line through the first via.

### RELATED APPLICATIONS

This application is a 35 U.S.C. 371 national stage application of PCT International Application No. PCT/CN2023/116040 filed on Aug. 31, 2023, the entire disclosure of which is incorporated herein by reference.

### TECHNICAL FIELD

The present disclosure relates to the field of display technology, and in particular, to a driving circuit structure, an array substrate, a display device, and a method of preparing an array substrate.

### BACKGROUND

In the field of display technology, such as a display panel, the pixel array of the display panel usually comprises multiple rows of gate lines and multiple columns of data lines intersecting with the gate lines. The driving of the gate lines can be achieved through a bonded integrated driving circuit. In recent years, with the improvement of the manufacturing process of amorphous silicon thin film transistors or oxide thin film transistors, the gate line driving circuits may also be directly integrated on the array substrate to form a GOA (Gate driver On Array) to drive the gate lines. For example, a GOA including multiple cascaded shift register units may be used to provide scanning signals for multiple rows of gate lines, thereby controlling the multiple rows of gate lines to turn on and turn off. Currently, more and more display panels use GOA technology to drive the gate lines. GOA technology helps realize the narrow frame design of a display panel and can reduce the production cost of a display panel.

### SUMMARY

According to an aspect of the present disclosure, a driving circuit structure is provided. The driving circuit structure comprises a base substrate; an initial signal line on the base substrate; a clock signal line on the base substrate; and a first insulating layer on a side of the initial signal line away from the base substrate and comprising a first via. The initial signal line is connected to the clock signal line through the first via.

In some embodiments, the driving circuit structure further comprises: a second insulating layer on a side of the first insulating layer away from the base substrate and comprising a second via; and a protective pad filling at least the second via. An orthographic projection of the protective pad on the base substrate at least partially overlaps with an orthographic projection of the first via on the base substrate.

In some embodiments, the clock signal line is on the side of the initial signal line away from the base substrate, a conductor is provided in the first via, an end of the conductor is directly connected to the initial signal line, and the other end of the conductor is directly connected to the clock signal line.

In some embodiments, an orthographic projection of the initial signal line on the base substrate partially overlaps with an orthographic projection of the clock signal line on the base substrate to form an overlapping region, and an orthographic projection of the first via on the base substrate falls within the overlapping region.

In some embodiments, the initial signal line and the clock signal line are in a same layer, and an orthographic projection of the initial signal line on the base substrate does not overlap with an orthographic projection of the clock signal line on the base substrate.

In some embodiments, the driving circuit structure further comprises: a first wiring group comprising at least one initial signal line extending along a first direction; a second wiring group comprising at least one clock signal line extending along the first direction, an orthographic projection of the second wiring group on the base substrate not overlapping with an orthographic projection of the first wiring group on the base substrate; and at least one first connection line extending along a second direction intersecting with the first direction and on a side of the first insulating layer away from the base substrate. The at least one clock signal line in the second wiring group is connected to any one of the initial signal lines in the first wiring group through the first connection line.

In some embodiments, the clock signal line comprises a hollow portion and a solid portion, an orthographic projection of the first connection line on the base substrate partially overlaps with an orthographic projection of the solid portion on the base substrate, and the orthographic projection of the first connection line and an orthographic projection of the first via on the base substrate do not overlap with an orthographic projection of the hollow portion on the base substrate.

In some embodiments, the driving circuit structure further comprises at least one second connection line extending along the second direction. Each clock signal line in the second wiring group is connected to a corresponding second connection line, and an orthographic projection of the first connection line on the base substrate does not overlap with an orthographic projection of the second connection line on the base substrate.

In some embodiments, the first insulating layer further comprises a plurality of groups of third vias, each clock signal line in the second wiring group is connected to the corresponding second connection line through a group of third vias among the plurality of groups of third vias.

In some embodiments, a clock signal line in the second wiring group has two cutting openings. One of the at least one first connection line is connected to the clock signal line having the two cutting openings, an orthographic projection of the first connection line on the base substrate partially overlaps with an orthographic projection of the clock signal line having the two cutting openings on the base substrate to form a first orthographic projection, an orthographic projection of the group of third vias among the plurality of groups of third vias on the base substrate is a second orthographic projection, the second orthographic projection falls within the orthographic projection of the clock signal line having the two cutting openings on the base substrate, and the first orthographic projection and the second orthographic projection are between orthographic projections of the two cutting openings on the base substrate.

In some embodiments, the first connection line comprises a first end and a second end opposite to each other, the first end of the first connection line is connected to any one of the initial signal lines in the first wiring group through the first via, and the second end of the first connection line is connected to any one of the clock signal lines in the second wiring group through the first via.

In some embodiments, the second wiring group comprises a plurality of clock signal lines arranged in parallel along the first direction, the first connection line spans the plurality of clock signal lines in the second wiring group along the second direction, the first connection line comprises a first end and a second end opposite to each other, the first end of the first connection line is connected to any one of the initial signal lines in the first wiring group through the first via, and an orthographic projection of the second end of the first connection line on the base substrate falls within an orthographic projection of a clock signal line among the plurality of clock signal lines in the second wiring group on the base substrate that is farthest from the initial signal line.

In some embodiments, the one of the at least one first connection line is welded to the clock signal line having the two cutting openings.

In some embodiments, the driving circuit structure further comprises a first power signal line and a second power signal line extending along the first direction. The first power signal line and the second power signal line are on a side of the second wiring group away from the first wiring group, and orthographic projections of the cutting openings of the clock signal line and an orthographic projection of a welding region on the base substrate do not overlap with orthographic projections of the first power signal line and the second power signal line on the base substrate.

In some embodiments, the one of the at least one first connection line is connected to the clock signal line having the two cutting openings through the first via.

In some embodiments, the first via comprises a first opening and a second opening opposite to each other, a shape of the first opening and the second opening is circular or elliptical, a longitudinal section of the first via is a rectangle or an inverted trapezoid, and the longitudinal section is parallel to a thickness direction of the base substrate.

According to another aspect of the present disclosure, an array substrate is provided, which comprises the driving circuit structure described in any of the previous embodiments.

In some embodiments, the array substrate further comprises: a first conductive layer in a same layer as the initial signal line; a second conductive layer on a side of the first insulating layer away from the base substrate, the first conductive layer being connected to the second conductive layer through a conductor in the first via; a second insulating layer on a side of the second conductive layer away from the base substrate and comprising a fourth via; and a third conductive layer on a side of the second insulating layer away from the base substrate and connected to the second conductive layer through the fourth via.

In some embodiments, the second insulating layer further comprises a fifth via, the third conductive layer fills the fourth via and the fifth via, and a depth of the fifth via is greater than a depth of the fourth via.

According to yet another aspect of the present disclosure, a display device is provided, which comprises the array substrate described in any of the previous embodiments.

In some embodiments, the display device comprises a display region and a peripheral region arranged around the display region, the driving circuit structure is arranged in the peripheral region.

According to still another aspect of the present disclosure, a method of preparing an array substrate is provided, which comprises: providing a base substrate; forming a plurality of initial signal lines on the base substrate; forming a plurality of clock signal lines on the base substrate; and forming a first insulating layer comprising a plurality of first vias on a side of the initial signal lines away from the base substrate, the initial signal lines being connected to the clock signal lines through the first vias.

In some embodiments, forming the initial signal lines, the clock signal lines, and the first insulating layer respectively by using different masks having a first size, so that the array substrate has a second size, the first size is larger than the second size, and the array substrate having the second size has a strip shape.

In some embodiments, the forming the plurality of initial signal lines, the plurality of clock signal lines, and the first insulating layer on the base substrate, comprises: depositing a first metal layer on the base substrate, patterning the first metal layer by blocking a portion of a first mask having the first size to form the plurality of initial signal lines; depositing a first intermediate insulating layer on the side of the initial signal lines away from the base substrate, patterning the first intermediate insulating layer by blocking a portion of a second mask having the first size to form the first insulating layer comprising the plurality of first vias, the first vias exposing a portion of a surface of the initial signal lines; depositing a second metal layer on a side of the first insulating layer away from the base substrate, patterning the second metal layer by blocking a portion of a third mask having the first size to simultaneously form the plurality of clock signal lines on the side of the first insulating layer away from the base substrate and a conductor in each of the first vias, one of the initial signal lines being connected to a respective one of the clock signal lines through the conductor; depositing a second intermediate insulating layer on a side of the clock signal lines away from the base substrate, patterning the second intermediate insulating layer by blocking a portion of the second mask to form a second insulating layer comprising a plurality of second vias, the second vias exposing a portion of a surface of the clock signal lines; and depositing a third metal layer on a side of the second insulating layer away from the base substrate, patterning the third metal layer by blocking a portion of a fourth mask having the first size to form a protective pad, the protective pad filling at least the second vias.

In some embodiments, the forming the plurality of initial signal lines and the plurality of clock signal lines on the base substrate, comprises: depositing a first metal layer on the base substrate, patterning the first metal layer by blocking a portion of a first mask having the first size to form a first wiring group and a second wiring group, the first wiring group comprising the plurality of initial signal lines arranged along a first direction, the second wiring group comprising the plurality of clock signal lines arranged along the first direction, an orthographic projection of the first wiring group on the base substrate not overlapping with an orthographic projection of the second wiring group on the base substrate.

In some embodiments, the method further comprises: depositing a first intermediate insulating layer on the side of the initial signal lines and the clock signal lines away from the base substrate, patterning the first intermediate insulating layer by blocking a portion of a second mask having the first size to form the first insulating layer comprising the plurality of first vias and a plurality of groups of third vias, the first vias exposing a portion of surfaces of the initial signal lines and the clock signal lines, and the third vias exposing a portion of a surface of the clock signal lines; depositing a second metal layer on a side of the first insulating layer away from the base substrate, patterning the second metal layer by blocking a portion of a third mask having the first size to form at least one first connection line and at least one second connection line arranged along a second direction, the first connection line comprising a first end and a second end opposite to each other, the first end of the first connection line being connected to any one of the initial signal lines in the first wiring group through the first vias, the second end of the first connection line being connected to any one of the clock signal lines in the second wiring group through the first vias, and each clock signal line in the second wiring group being connected to a corresponding second connection line through a group of third vias among the plurality of groups of third vias, the second direction intersecting with the first direction; depositing a second intermediate insulating layer on a side of the first connection line and the second connection line away from the base substrate, patterning the second intermediate insulating layer by blocking a portion of the second mask to form a second insulating layer comprising a plurality of second vias; depositing a third metal layer on a side of the second insulating layer away from the base substrate, patterning the third metal layer by blocking a portion of a fourth mask having the first size to form a protective pad, the protective pad filling at least the second vias; and cutting a clock signal line in the second wiring group to make the clock signal line have two cutting openings. An orthographic projection of the first connection line connected to the clock signal line having the two cutting openings on the base substrate partially overlaps with an orthographic projection of the clock signal line having the two cutting openings on the base substrate to form a first orthographic projection, an orthographic projection of the group of third vias among the plurality of groups of third vias on the base substrate is a second orthographic projection, the second orthographic projection falls within the orthographic projection of the clock signal line having the two cutting openings on the base substrate, and the first orthographic projection and the second orthographic projection are between orthographic projections of the two cutting openings on the base substrate.

In some embodiments, the method further comprises: sequentially depositing a first intermediate insulating layer and a second metal layer on the side of the initial signal lines and the clock signal lines away from the base substrate, patterning the first intermediate insulating layer and the second metal layer by blocking a portion of a second mask having the first size to form the first insulating layer comprising the plurality of first vias and a plurality of groups of third vias as well as at least one first connection line and at least one second connection line arranged along a second direction. The first vias expose a portion of a surface of the initial signal lines, and the third vias expose a portion of a surface of the clock signal lines, the first connection line spans the plurality of clock signal lines in the second wiring group along the second direction, the first connection line comprises a first end and a second end opposite to each other, the first end of the first connection line is connected to any one of the initial signal lines in the first wiring group through the first vias, an orthographic projection of the second end of the first connection line on the base substrate falls within an orthographic projection of a clock signal line among the plurality of clock signal lines in the second wiring group on the base substrate that is farthest from the initial signal lines, and each clock signal line in the second wiring group is connected to a corresponding second connection line through a group of third vias among the plurality of groups of third vias, the second direction intersects with the first direction; depositing a second intermediate insulating layer on a side of the first connection line and the second connection line away from the base substrate, patterning the second intermediate insulating layer by blocking a portion of a third mask having the first size to form a second insulating layer; depositing a third metal layer on a side of the second insulating layer away from the base substrate, patterning the third metal layer by blocking a portion of a fourth mask having the first size to form a pixel electrode; cutting a clock signal line in the second wiring group to make the clock signal line have two cutting openings; and welding the clock signal line having the two cutting openings and the first connection line between the two cutting openings in a welding region. An orthographic projection of the welding region on the base substrate is a first orthographic projection, an orthographic projection of the group of third vias among the plurality of groups of third vias on the base substrate is a second orthographic projection, the second orthographic projection falls within an orthographic projection of the clock signal line having the two cutting openings on the base substrate, and the first orthographic projection and the second orthographic projection are between orthographic projections of the two cutting openings on the base substrate.

### BRIEF DESCRIPTION OF THE DRAWINGS

Various exemplary embodiments of the present disclosure will be described in detail below with reference to the accompanying drawings, in which:

FIG. 1 illustrates a schematic layout of a driving circuit;

FIG. 2 illustrates an enlarged view of region 1 in FIG. 1;

FIG. 3 illustrates a top view and a cross-sectional view of a partial region of a driving circuit structure according to an embodiment of the present disclosure;

FIG. 4 illustrates a schematic plan view of a circuit layout of a driving circuit structure according to an embodiment of the present disclosure;

FIG. 5 illustrates an electron microscope picture of the first via according to an embodiment of the present disclosure;

FIG. 6 illustrates an electron microscope picture of a partial region of a driving circuit structure during the preparation process according to an embodiment of the present disclosure;

FIG. 7 illustrates a top view under an electron microscope of a partial region of a driving circuit structure during the preparation process according to an embodiment of the present disclosure;

FIG. 8 illustrates a cross-sectional view taken along the line of the driving circuit structure of FIG. 7;

FIG. 9 illustrates a schematic diagram of a circuit layout of a driving circuit structure according to an embodiment of the present disclosure;

FIG. 10 illustrates a cross-sectional view of a partial region taken along the line BB′ of the driving circuit structure of FIG. 9;

FIG. 11 illustrates a cross-sectional view of a partial region of a driving circuit structure;

FIG. 12 illustrates a schematic diagram of a circuit layout of a driving circuit structure according to an embodiment of the present disclosure;

FIG. 13 illustrates a schematic diagram of a circuit layout of a driving circuit structure according to an embodiment of the present disclosure;

FIG. 14 illustrates a structural diagram of a partial region of an array substrate;

FIG. 15 illustrates a top view of a partial region of an array substrate according to an embodiment of the present disclosure;

FIG. 16 illustrates a cross-sectional view of a partial region taken along the line CC′ of the array substrate of FIG. 15;

FIG. 17 illustrates comparative data of contact resistance and current withstand value parameter of a conventional array substrate and an array substrate according to an embodiment of the present disclosure;

FIG. 18 illustrates a structural diagram of a display device according to an embodiment of the present disclosure;

FIG. 19 illustrates a flow chart of a method of preparing an array substrate according to an embodiment of the present disclosure;

FIG. 20 illustrates a schematic diagram of using a mask with a first size to respectively prepare a product with the first size and a product with a second size according to an embodiment of the present disclosure;

FIG. 21 illustrates a schematic diagram of preparing a first metal layer using a method provided by an embodiment of the present disclosure;

FIG. 22 illustrates a schematic diagram of preparing a first insulating layer using a method provided by an embodiment of the present disclosure;

FIG. 23 illustrates a schematic diagram of preparing a second metal layer using a method provided by an embodiment of the present disclosure;

FIG. 24 illustrates a schematic diagram of preparing a second insulating layer using a method provided by an embodiment of the present disclosure; and

FIG. 25 illustrates a schematic diagram of preparing a third metal layer using a method provided by an embodiment of the present disclosure.

It should be understood that the drawings are only schematic illustrations of exemplary embodiments of the present disclosure, which are not limitations of the present disclosure and not necessarily drawn to scale. Moreover, the same or similar reference numerals in various drawings generally refer to the same or similar parts.

### DETAILED DESCRIPTION OF THE DISCLOSURE

The technical solutions in the embodiments of the present disclosure will be clearly described below with reference to the accompanying drawings. Obviously, the described embodiments are only some, but not all, of the embodiments of the present disclosure. Based on the embodiments of the present disclosure, all other embodiments obtained by those of ordinary skill in the art without undue experimentation fall within the scope of protection of this disclosure.

Before formally describing the technical solutions of the embodiments of the present disclosure, some terms used in the embodiments of the present disclosure are explained and defined as follows to help those skilled in the art understand the technical solutions of the embodiments of the present disclosure more clearly.

As used herein, terms such as “A and B are in the same layer” mean that A and B are formed through the same patterning process, but this does not limit that the layer A and the layer B must have the same height or thickness. In the case of “A and B are in the same layer”, the layer A and the layer B are usually made of the same material. Similarly, terms such as “A and B are in different layers” mean that, A and B are usually formed by different patterning processes, the layer A and the layer B may be made of the same material or different materials, and the layer A and the layer B may have the same height and/or thickness or have different heights and/or thicknesses.

As used herein, the term “patterning process” or “patterning” comprises, but is not limited to, processes such as depositing a film, coating photoresist, exposure, development, etching, and stripping photoresist. After “patterning process” or “patterning”, the “layer” comprises at least one pattern.

GOA technology is a technology that integrates the gate driving circuits on an array substrate to form a scanning drive for gate lines, which can improve the integration of the array substrate and reduce the number of the gate driving circuits. GOA technology helps realize the narrow frame design of a display panel and can reduce the production cost of a display panel.

In order to further reduce product development cost and to quickly respond to customer needs for products of different sizes, the inventor(s) of this application found that the mask used to prepare products of existing sizes can be used to prepare another product(s) of other sizes by blocking exposure and partial exposure. Since GOA products usually place an initial signal line (or referred to as a STV wiring) of GOA on the opposite side of the data line pad, when sharing the mask of existing product to prepare other products of different sizes, some GOA units and initial signal lines need to be cut off. This prevents the STV signal on the initial signal line from being transmitted to the GOA unit, causing the product to not work properly.

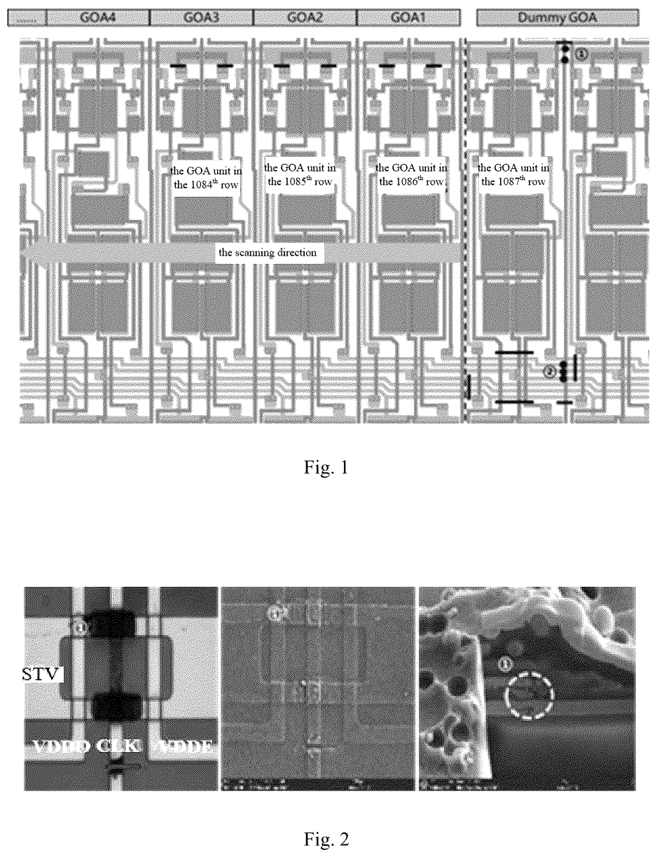

Currently, one way to solve the above problem is to use a cutting and welding maintenance method, which uses a clock signal line (or referred to as a CLK wiring) to introduce the STV signal to realize GOA driving. FIG. 1 illustrates five rows of GOA units, namely GOA1˜GOA4 and a Dummy GOA, GOA3 is the GOA unit in the 1084^{th} row, GOA2 is the GOA unit in the 1085^{th} row, GOA1 is the GOA unit in the 1086^{th} row, Dummy GOA is the GOA unit in the 1087^{th} row, and the scanning direction is from GOA1 to GOA4. As mentioned above, in order to share the mask of existing product to prepare a product of another size, it is necessary to cut off some structures of GOA1˜GOA3. The cutting position is the position illustrated by the black solid line in FIG. 1, and a number of the cutting positions is about 12. In order to use the CLK wiring to introduce the STV signal, the CLK wiring and the STV wiring need to be welded. FIG. 1 illustrates 5 welding positions, wherein two welding positions are illustrated at \textcircled{1}, and three welding positions are illustrated at \textcircled{2}. By welding the CLK wiring and the STV wiring, the STV signal at point \textcircled{1} can be introduced to the three lines at point \textcircled{2} by using the CLK wiring. The three lines at point \textcircled{2} are connected to the GOA1˜GOA3 units respectively, so that the STV signal can be introduced to the GOA1˜GOA3 units.

FIG. 2 is a partial enlarged view of \textcircled{1} in FIG. 1. As illustrated in FIG. 2, a VDDO wiring and a VDDE wiring are arranged on both sides of the CLK wiring. Both the VDDO wiring and the VDDE wiring partially overlap with the STV wiring. The STV wiring, the CLK wiring, the VDDO wiring, and the VDDE wiring are arranged relatively closely to each other. During welding the STV wiring and the CLK wiring at the maintenance point \textcircled{1}, it is easy to cause the STV wiring to be short-circuited with the adjacent VDDO wiring and/or VDDE wiring, causing the display panel to display abnormally or even fail to display, and reducing the production yield of products.

In view of this, embodiments of the present disclosure provide some driving circuit structures. These driving circuit structures comprise: a base substrate, an initial signal line (also referred to as a STV wiring) on the base substrate, a clock signal line (also referred to as a CLK wiring) on the base substrate, and a first insulating layer on a side of the initial signal line away from the base substrate. The first insulating layer comprises a first via, and the initial signal line is connected to the clock signal line through the first via. The driving circuit structure may be, for example, a gate driving circuit structure, which may use a GOA including multiple cascaded shift register units to provide scanning signals for multiple rows of gate lines, thereby controlling the multiple rows of gate lines to turn on and turn off.

It should be noted that the phrase “the initial signal line is connected to the clock signal line through the first via” means that the connection between the initial signal line and the clock signal line requires the participation of the first via, but this does not exclude the presence of other electrical elements. For example, the initial signal line may be connected to the clock signal line only through the first via (and the conductive material in the first via), that is, one end of the first via is directly connected to the initial signal line, and the other end of the first via is directly connected to the clock signal line. Alternatively, the initial signal line may be connected to the clock signal line through the first via and other electrical elements (comprising but not limited to wires).

In the driving circuit structures provided by the embodiments of the present disclosure, the initial signal line is connected to the clock signal line through the first via, thereby introducing the STV signal on the initial signal line to the GOA unit. In this way, a short circuit between the initial signal line and other wirings can be avoided, so that the display panel can display normally, which helps to improve the production yield of the display panel.

With the help of several exemplary embodiments, the arrangement of driving circuit structures provided by the embodiments of the present disclosure will be introduced in more detail below.

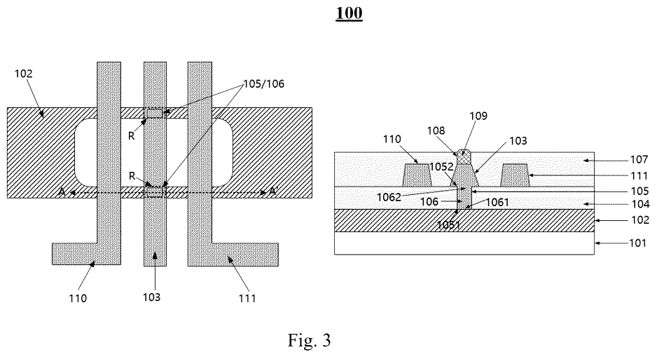

FIG. 3 illustrates a schematic diagram of a partial region of a driving circuit structure 100, where the left diagram is a top view of a partial region of the driving circuit structure 100, and the right diagram is a cross-sectional view taken along the line AA′ of the left diagram. As illustrated in FIG. 3, the driving circuit structure 100 comprises: a base substrate 101, an initial signal line 102 arranged on the base substrate 101, a first insulating layer 104 located on a side of the initial signal line 102 away from the base substrate 101, and a clock signal line 103 located on a side of the first insulating layer 104 away from the base substrate 101. The first insulating layer 104 comprises a first via 105, the initial signal line 102 is connected to the clock signal line 103 through the first via 105. More specifically, as illustrated in FIG. 3, a conductor 106 is provided in the first via 105, one end 1061 of the conductor 106 is directly connected to the initial signal line 102, and the other end 1062 of the conductor 106 is directly connected to the clock signal line 103, so that the initial signal line 102 is connected to the clock signal line 103 through the conductor 106 in the first via 105.

The initial signal line 102 is connected to the clock signal line 103 through the conductor 106 in the first via 105, instead of connected to the clock signal line 103 by welding. In this way, a short circuit between the initial signal line 102 and other surrounding wirings during the welding process can be avoided, so that the display panel comprising the driving circuit structure 100 can display normally. In addition, since the depth of the first via 105 is usually shallow (for example, the depth is about a few hundred nanometers), using the first via 105 to connect the initial signal line 102 and the clock signal line 103 can improve the reliability and success rate of the connection between the initial signal line 102 and the clock signal line 103, which helps to significantly improve the production yield of the display panel comprising the driving circuit structure 100. If the first via 105 has a deep depth, during the process of etching the first insulating layer 104 to form the first via 105, due to the metal-induced plasma effect, the etching rate of the portion of the first insulating layer 104 close to the clock signal line 103 is usually greater than the etching rate of other portions of the first insulating layer 104, which may easily cause the first insulating layer 104 under the clock signal line 103 to be hollowed out, thereby forming an undercut. The existence of undercut may cause other layers to break at the undercut, leading to problems such as abnormal connections and electrostatic breakdown. In contrast, in the driving circuit structure 100 of FIG. 3, the first via 105 has a shallower depth. In the process of forming the first via 105, the undercut will not be formed in the first insulating layer 104, which can avoid the negative impact of undercut and help improve the reliability of the product. In addition, the existence of the first via 105 can improve the identification of maintenance points, which helps to improve the efficiency of maintenance personnel and the success of maintenance.

The initial signal line 102 can be used to provide a start signal (STV signal) for the driving circuit structure 100, and the clock signal line 103 can be used to provide a clock signal for the driving circuit structure 100, and at least one clock signal line 103 can be used to transmit the STV signal on the initial signal line 102 for the driving circuit structure 100.

The first via 105 penetrates the first insulating layer 104 and comprises a first opening 1051 and a second opening 1052 opposite to each other. The shapes of the first opening 1051 and the second opening 1052 may be circular or elliptical. For example, the longitudinal section of the first via 105 may be a rectangle or an inverted trapezoid, the longitudinal section of the first via 105 is the section illustrated in the right diagram of FIG. 3, and the section is parallel to the thickness direction of the base substrate 101. The inverted trapezoidal first via 105 is more conducive to the connection between the clock signal line 103 and the initial signal line 102, making the via resistance smaller.

It should be noted that the first insulating layer 104 comprises several first vias 105, but not all of the first vias 105 are used to connect the initial signal line 102 and the clock signal line 103. For example, some of the first vias 105 may be used to connect the initial signal line 102 with the clock signal line 103, and some of the first vias 105 may be used to connect the initial signal line 102 with other wirings or to connect a metal layer located in the same layer as the initial signal line 102 with other metal layers.

As illustrated in FIG. 3, the initial signal line 102 and the clock signal line 103 are located in different layers. For example, the initial signal line 102 may be located in the same layer as a gate line, a gate electrode, etc., and the same mask may be used to form the initial signal line 102, the gate line, and the gate electrode. The clock signal line 103 may be located in the same layer as a first power signal line 110, a second power signal line 111, and a source/drain electrode (not illustrated), etc., for example. The same mask may be used to form the clock signal line 103, the first power signal line 110, the second power signal line 111, and the source/drain electrode. An orthographic projection of the initial signal line 102 on the base substrate 101 partially overlaps with an orthographic projection of the clock signal line 103 on the base substrate 101 to form an overlapping region R, and an orthographic projection of the first via 105 on the base substrate 101 falls within the overlapping region R.

The first power signal line 110 (for example, it may be a VDDO wiring) and the second power signal line 111 (for example, it may be a VDDE wiring) can be used to transmit voltage signals. As illustrated in FIG. 3, the first power signal line 110 and the second power signal line 111 are arranged on both sides of the clock signal line 103, and the orthographic projections of the first power signal line 110 and the second power signal line 111 on the base substrate 101 partially overlap with the orthographic projection of the initial signal line 102 on the base substrate 101. Since the initial signal line 102 and the clock signal line 103 are connected by means of the first via 105 rather than by means of welding, even if the first power signal line 110 and the second power signal line 111 are both arranged close to the initial signal line 102, the initial signal line 102 is not short-circuited with the adjacent first power signal line 110 and/or the second power signal line 111, thereby ensuring normal display of the display panel and helping to improve the production yield of the product.

In some embodiments, the driving circuit structure 100 may further comprise a second insulating layer 107 and a protective pad 109. The second insulating layer 107 is located on a side of the clock signal line 103 away from the base substrate 101 and comprises a second via 108. The protective pad 109 fills at least the second via 108, and the orthographic projection of the protective pad 109 on the base substrate 101 at least partially overlaps with the orthographic projection of the first via 105 on the base substrate 101. The protective pad 109 may cover the surface of the clock signal line 103 exposed by the second via 108. The protective pad 109 can be used to prevent external water vapor from corroding the clock signal line 103 and the conductor 106 in the first via 105, to protect the clock signal line 103 and the conductor 106 in the first via 105.

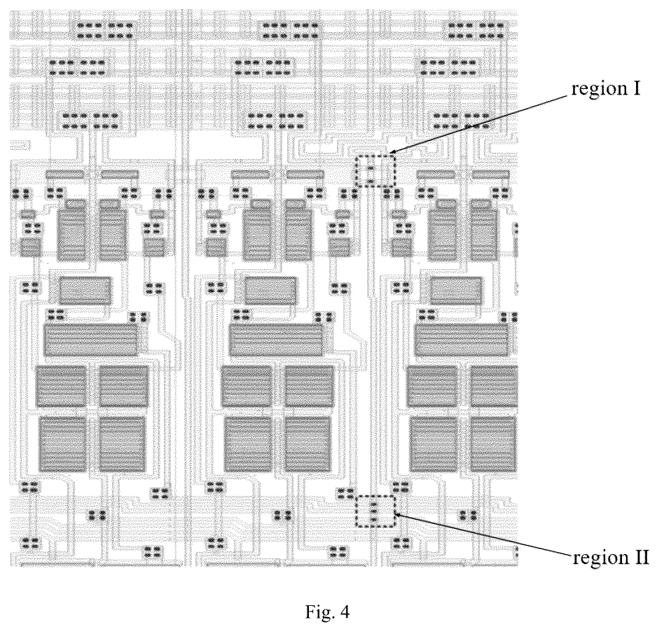

FIG. 4 illustrates a schematic layout of the driving circuit structure 100 on the array substrate, which illustrates regions I and II. The enlarged view of the region I in FIG. 4 is the left diagram of FIG. 3. The region I of FIG. 4 illustrates two first vias 105, and the region II illustrates three first vias 105. In the region I, the initial signal line 102 is connected to the clock signal line 103 through two first vias 105, the clock signal line 103 is connected to three horizontal connecting lines through three first vias 105 in the region II, and the three horizontal connecting lines are respectively connected to the corresponding GOA units. In this way, the STV signal on the initial signal line 102 can be introduced into the corresponding GOA unit through the clock signal line 103 to realize GOA driving.

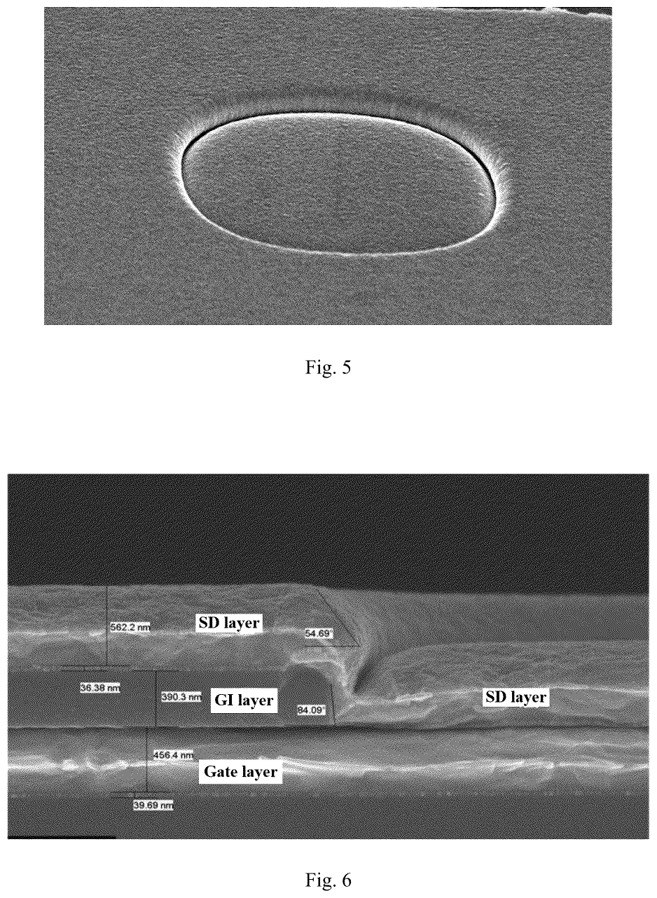

FIG. 5 is a top view of the first via 105, which is an electron microscope picture of the first via 105. As illustrated in the figure, the shape of the first via 105 may be circular or elliptical, and its size may be determined according to product requirements.

FIG. 6 is a cross-sectional view after depositing the SD metal layer, which is an electron microscope picture. In FIG. 6, the Gate layer may be the initial signal line 102, the gate line, the gate electrode, and the like as mentioned above; the GI layer represents the first insulating layer 104 as mentioned above, which may be a gate insulating layer; the SD layer may be the clock signal line 103, the first power signal line 110, the second power signal line 111, the source/drain electrode, and the like. As illustrated in the figure, the first via 105 in the GI layer is filled by the SD layer, in this way, the Gate layer is connected to the SD layer through the first via 105, thereby avoiding the short circuit problem caused by welding. For example, the thickness of the Gate layer may be approximately 456.4 nm, the thickness of the GI layer may be approximately 390.3 nm, the thickness of the SD layer may be approximately 562.2 nm, the thickness of an intermediate layer between the GI layer and the SD layer may be approximately 36.38 nm, and the thickness of an intermediate layer between the Gate layer and the base substrate may be approximately 39.69 nm. In some examples, the slope angle of the portion of the SD layer near the first via 105 of the GI layer is approximately 54.69°. In some examples, the first via 105 may be in an inverted trapezoid shape, and the slope angle of the side surface of the first via 105 is approximately 84.09°.

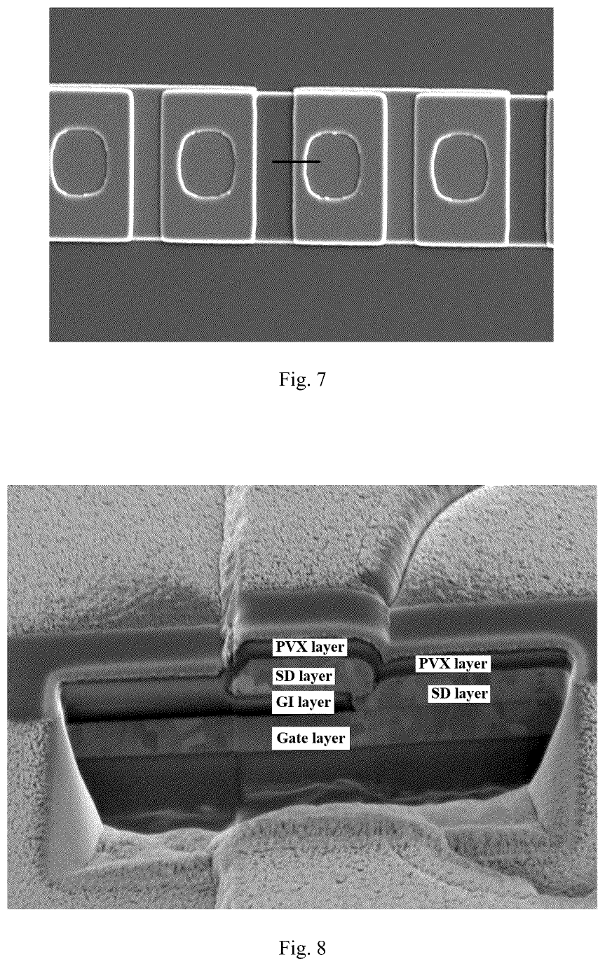

FIG. 7 illustrates an electron microscope picture after the second insulating layer 107 (also referred to as a PVX layer) is formed on the SD layer, and FIG. 8 is a cross-sectional view taken along the black solid line of FIG. 7. As illustrated in FIGS. 7 and 8, the SD layer is not only located on the side of the GI layer away from the Gate layer, but also filled in the first via 105 of the GI layer. The PVX layer is located on the side of the SD layer away from the GI layer, and the SD layer in the first via 105 is wrapped by the PVX layer.

The display panel comprising the above-mentioned driving circuit structure 100 may be a display panel of various appropriate types and various appropriate sizes. For example, the display panel comprising the above-mentioned driving circuit structure 100 may be a display panel with a strip shape, which may be installed on a subway for display, for example. In some embodiments, the display panel comprising the above-mentioned driving circuit structure 100 is a strip screen with a size of 58.5 inches. The existing 65-inch mask for non-strip screens (such as the mask used to prepare 65-inch TVs) may be optimized and designed, for example, the pattern of the first via 105 and/or the pattern of the protective pad 109 is added to the 65-inch mask, and then the optimized 65-inch mask is used to prepare a 58.5-inch strip screen, so as to realize the sharing of the mask. The specific preparation method will be described later and will not be described here.

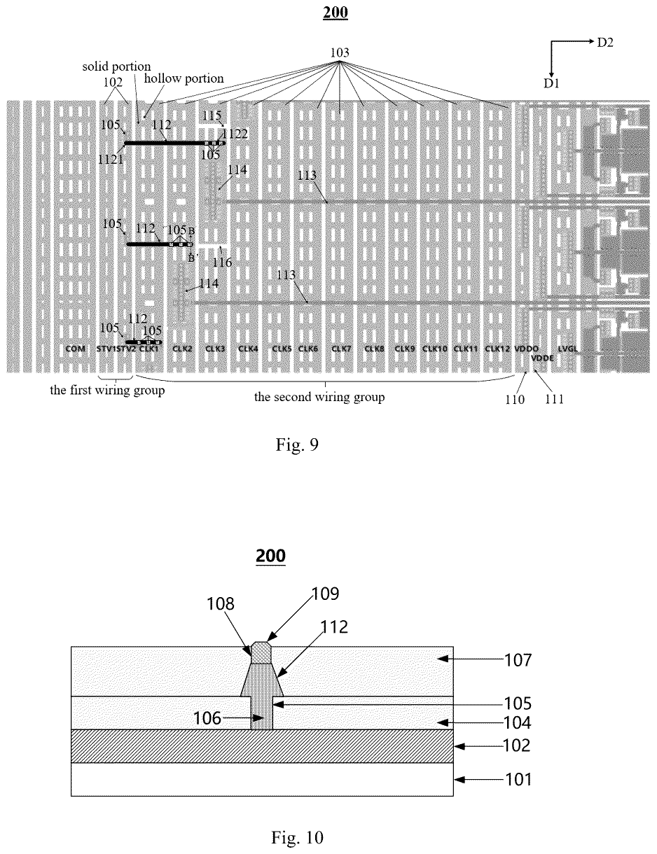

FIG. 9 illustrates a schematic layout of another driving circuit structure 200. Different from the driving circuit structure 100, in this driving circuit structure 200, the initial signal line 102 and the clock signal line 103 are in the same layer.

FIG. 10 illustrates a cross-sectional view taken along the line BB′ of FIG. 9. As illustrated in FIGS. 9 and 10, the driving circuit structure 200 comprises: a base substrate 101; a first wiring group which is arranged on the base substrate 101 and comprises at least one initial signal line 102 extending along the first direction D1; a second wiring group which is arranged on the base substrate 101 and comprises at least one clock signal line 103 extending along the first direction D1. The initial signal line 102 and the clock signal line 103 are in the same layer, and the orthographic projection of each initial signal line 102 on the base substrate 101 does not overlap with the orthographic projection of each clock signal line 103 on the base substrate 101. As an example, FIG. 9 illustrates that the first wiring group comprises two initial signal lines 102, respectively represented as STV1 and STV2. Of course, this is only an example, and the first wiring group may comprise more initial signal lines. FIG. 9 illustrates that the second wiring group comprises 12 clock signal lines 103, respectively represented as CLK1˜CLK12. Of course, this is only an example, and the second wiring group may comprise more or less clock signal lines. This embodiment of the present disclosure does not limit the number of initial signal lines 102 and clock signal lines 103.

The inventor(s) of the present application found that in a product in which the initial signal line 102 and the clock signal line 103 are located in different layers, when preparing the clock signal line 103, the metal layer where the clock signal line 103 is located needs to climb over the metal layer where the initial signal line 102 is located, and the two metal layers will overlap. Since the initial signal line 102 has a certain thickness, when the clock signal line 103 climbs over the initial signal line 102, the wirings may be disconnected. Therefore, during the preparation and detection process, it is necessary to pay attention to whether the relevant wirings are disconnected. In the driving circuit structure 200, the initial signal line 102 and the clock signal line 103 are located in the same layer, which can reduce or even avoid the disconnection of the clock signal line 103. In addition, the initial signal line 102 and the clock signal line 103 do not overlap with each other, which helps to reduce the load of the signal lines.

As illustrated in FIGS. 9 and 10, the driving circuit structure 200 also comprises: a first insulating layer 104 located on the side of the initial signal line 102 and the clock signal line 103 away from the base substrate 101, the first insulating layer 104 comprising a plurality of first vias 105 and a plurality of groups of third vias 114; at least one first connection line 112 extending along the second direction D2 and located on the side of the first insulating layer 104 away from the base substrate 101; and at least one second connection line 113 extending along the second direction D2 and located in the same layer as the first connection line 112. The first direction D1 intersects with the second direction D2. For the sake of simplicity, FIG. 9 only schematically illustrates three first connection lines 112 and two second connection lines 113, but in fact, the number of first connection lines 112 may be arbitrary. For example, the number of the first connection lines 112 may be equal to the number of the clock signal lines 103 in the second wiring group. The number of the second connection lines 113 may also be arbitrary. For example, the number of the second connection lines 113 may be equal to the number of the clock signal lines 103 in the second wiring group.

The first connection line 112 comprises a first end 1121 and a second end 1122 opposite to each other. The first end 1121 of the first connection line 112 is connected to any initial signal line 102 in the first wiring group through the first via 105. The second end 1122 of the first connection line 112 is connected to any clock signal line 113 in the second wiring group through another first via 105. For example, for the embodiment of FIG. 9, twelve first connection lines 112 may be provided. The first end 1121 of one of the twelve first connection lines 112 may be connected to any one of the initial signal lines STV1 and STV2 through the first via 105, the second end 1122 of the first connection line 112 may be connected to any one of the clock signal lines CLK1 to CLK12 through another first via 105. The first end 1121 of another one of the twelve first connection lines 112 may be connected to any one of the initial signal lines STV1 and STV2 through the first via 105, and the second end 1122 of the first connection line 112 may be connected to any one of the remaining 11 clock signal lines through another first via 105, and so on. In this way, the first end 1121 of each first connection line 112 is connected to the initial signal line 102 through the first via 105, and the second end 1122 of each first connection line 112 is connected to the clock signal line 103 through the first via 105. In addition, each clock signal line 103 in the second wiring group is connected to a corresponding second connection line 113 through a group of third vias 114, the other end of the second connection line 113 that is not connected to the clock signal line 103 can be connected to the GOA unit, thereby realizing a complete signal transmission path.

Any clock signal line in the second wiring group has two cutting openings 115 and 116. The clock signal line that is cut in the second wiring group is the clock signal line that is selected to transmit the STV signal on the initial signal line 102, and the clock signal lines that are not cut do not transmit the STV signal. Any one of the clock signal lines CLK1˜CLK12 can be selected to transmit the STV signal. FIG. 9 takes the transmission of the STV signal through the clock signal line CLK3 as an example. As illustrated in FIG. 9, the clock signal line CLK3 has two cutting openings 115 and 116, the first end 1121 of the first connection line 112 is connected to the initial signal line STV2 through the first via 105, and the second end 1122 of the first connection line 112 is connected to the clock signal line CLK3 through the first via 105. An orthographic projection of the first connection line 112 on the base substrate 101 partially overlaps with an orthographic projection of the clock signal line CLK3 on the base substrate 101, and a portion where the orthographic projection of the first connection line 112 on the base substrate 101 overlaps with the orthographic projection of the clock signal line CLK3 on the base substrate 101 forms a first orthographic projection. The clock signal line CLK3 is connected to the second connection line 113 through a group of third vias 114, and the second orthographic projection of the group of third vias 114 on the base substrate 101 falls within the orthographic projection of the clock signal line CLK3 on the base substrate 101. The first orthographic projection and the second orthographic projection need to be located between the orthographic projections of the two cutting openings 115 and 116 on the base substrate 101 to form an effective transmission path for the STV signal. The clock signal line CLK3 is selected to transmit the STV signal. The effective transmission path of the STV signal is: the STV signal on the initial signal line STV2 is transmitted to the clock signal line CLK3 through the first connection line 112, and the clock signal line CLK3 transmits the STV signal to the GOA unit through the second connection line 113.

Each clock signal line in the second wiring group can be connected to a corresponding first connection line 112. In this way, even if some clock signal line is found to be broken during the production process, one of the other unbroken clock signal lines can be selected for cutting to transmit the STV signal. This design greatly increases the selectivity of cutting positions. In addition, in the driving circuit structure 200, the initial signal line 102 is connected to the first connection line 112 through the first via 105, and the first connection line 112 is connected to the clock signal line 103 through the first via 105. That is, the initial signal line 102 is connected to the clock signal line 103 through the first via 105 and the first connection line 112, thereby avoiding welding of the initial signal line 102 and the clock signal line 103. Therefore, in the driving circuit structure 200, the clock signal line 103 only needs to be cut but does not need to be welded, so that the STV signal can be introduced into the GOA unit through the clock signal line 103 to achieve GOA driving.

As illustrated in FIG. 9, in order to reduce resistance, the initial signal line 102 and the clock signal line 103 are designed to comprise hollow portions and solid portions. The orthographic projection of the first connection line 112 on the base substrate 101 may partially overlap with the orthographic projection of the solid portion of the clock signal line 103 on the base substrate 101. However, the orthographic projections of the first connection line 112 and the first via 105 on the base substrate 101 do not overlap with the orthographic projection of the hollow portion of the clock signal line 103 on the base substrate 101, that is, the hollow portion of the clock signal line 103 is avoided. Since the first connection line 112 and the clock signal line 103 are located in different layers, by keeping the first connection line 112 and the first via 105 away from the hollow portion of the clock signal line 103, the disconnection problem that may occur when the first connection line 112 climbs over the clock signal line 103 with a certain thickness can be reduced or even avoided, therefore, the success rate of connection between the clock signal line 103 and the first connection line 112 can be improved.

In some embodiments, the orthographic projection of the first connection line 112 on the base substrate 101 does not overlap with the orthographic projection of the second connection line 113 on the base substrate 101, so that a short circuit between the first connection line 112 and the second connection line 113 can be avoided. For example, the orthographic projection of the first connection line 112 on the base substrate 101 does not overlap with the orthographic projection of the third via 114 on the base substrate 101.

As illustrated in FIG. 9, the driving circuit structure 200 may also comprise a first power signal line 110 (or referred to as a VDDO wiring), a second power signal line 111 (or referred to as a VDDE wiring), a common electrode line COM, a third power signal line LVGL that are extending along the first direction D1. The second wiring group is located between the first wiring group and the first power signal line 110, and the display region of the display panel may be located on a side of the third power signal line LVGL away from the second wiring group.

As illustrated in FIG. 10, in some embodiments, the driving circuit structure 200 may also comprise a second insulating layer 107 and a protective pad 109, the second insulating layer 107 is located on a side of the first connection line 112 away from the base substrate 101 and comprises a second via 108. The protective pad 109 fills at least the second via 108, and the orthographic projection of the protection pad 109 on the base substrate 101 at least partially overlaps with the orthographic projection of the first via 105 on the base substrate 101. The protective pad 109 may cover the surface of the first connection line 112 exposed by the second via 108. The protective pad 109 can be used to prevent external water vapor from corroding the first connection line 112 and the conductor 106 in the first via 105 to protect the first connection line 112 and the conductor 106 in the first via 105. The first connection line 112 and the conductor 106 may be formed through the same patterning process.

The display panel comprising the above-mentioned driving circuit structure 200 may be a display panel of various appropriate types and various sizes. For example, the display panel comprising the above-mentioned driving circuit structure 200 may be a display panel with a strip shape, which may be installed on a subway for display, for example. In some embodiments, the display panel comprising the above-mentioned driving circuit structure 200 is a strip screen with a size of 58.5 inches. The existing 65-inch mask may be optimized and designed, for example, the pattern of the first via 105, the pattern of the first connection line 112, and the pattern of the protective pad 109 are added in advance to the existing 65-inch mask, and then the optimized 65-inch mask is used to prepare a 58.5-inch strip screen, so as to realize the sharing of the mask. The specific preparation method will be described later and will not be described here.

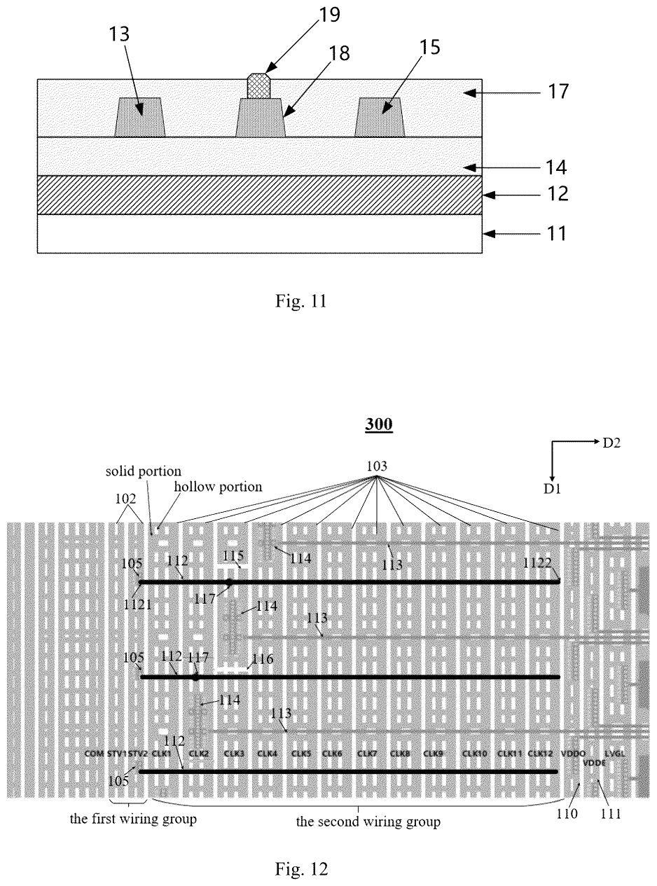

Of course, the optimized 65-inch mask can continue to be used to prepare 65-inch non-strip screen products (such as TVs) without any adverse impact on the structure of non-strip screen products. For example, FIG. 11 illustrates a cross-sectional view of a partial region of a driving circuit structure of a non-strip screen product. As illustrated in FIG. 11, the driving circuit structure comprises a substrate 11, an initial signal line 12, a first insulating layer 14, a second insulating layer 17, a clock signal line 18, a protective pad 19.

FIG. 12 illustrates a schematic layout of yet another driving circuit structure 300. Different from the driving circuit structure 100, in this driving circuit structure 300, the initial signal line 102 and the clock signal line 103 are located in the same layer.

As illustrated in FIG. 12, the driving circuit structure 300 comprises: a base substrate 101 (not illustrated); a first wiring group which is arranged on the base substrate 101 and comprises at least one initial signal line 102 extending along the first direction D1; a second wiring group which is arranged on the base substrate 101 and comprises at least one clock signal line 103 extending along the first direction D1. The initial signal line 102 and the clock signal line 103 are located in the same layer. The orthographic projection of each initial signal line 102 on the base substrate 101 does not overlap with the orthographic projection of each clock signal line 103 on the base substrate 101. As an example, FIG. 12 illustrates that the first wiring group comprises two initial signal lines 102, respectively represented as STV1 and STV2. Of course, this is only an example, and the first wiring group may comprise more initial signal lines 102. As an example, FIG. 12 illustrates that the second wiring group comprises 12 clock signal lines 103, respectively represented as CLK1˜CLK12. Of course, this is only an example, and the second wiring group may comprise more or fewer clock signal lines 103. This embodiment of the present disclosure does not limit the number of initial signal lines 102 and clock signal lines 103. In the driving circuit structure 300, the initial signal line 102 and the clock signal line 103 are located in the same layer, which can prevent the clock signal line 103 from climbing over the initial signal line 102 with a certain thickness, thereby reducing or even avoiding the disconnection problem of the clock signal line 103. In addition, the initial signal line 102 and the clock signal line 103 do not overlap with each other, which helps to reduce the load of the signal lines.

The driving circuit structure 300 also comprises: a first insulating layer 104 located on the side of the initial signal line 102 and the clock signal line 103 away from the base substrate 101, the first insulating layer 104 comprising a plurality of first vias 105 and a plurality of groups of third vias 114; at least one first connection line 112 extending along the second direction D2 and located on the side of the first insulating layer 104 away from the base substrate 101; and at least one second connection line 113 extending along the second direction D2 and located in the same layer as the first connection line 112. For the sake of simplicity, FIG. 12 only schematically illustrates three first connection lines 112 and three second connection lines 113, but in fact, any number of first connection lines 112 may be arranged, as long as the first connection lines 112 avoid the third via 114 and the hollow region of the clock signal line 103. The number of the second connection lines 113 may be equal to the number of the clock signal lines 103 in the second wiring group.

The first connection line 112 comprises a first end 1121 and a second end 1122 opposite to each other. The first end 1121 of the first connection line 112 is connected to any initial signal line 102 in the first wiring group through the first via 105, the orthographic projection of the second end 1122 of the first connection line 112 on the base substrate 101 falls within the orthographic projection of a clock signal line 103 among the plurality of clock signal lines in the second wiring group on the base substrate 101 that is farthest from the initial signal line 102, that is, the first connection line 112 spans the plurality of clock signal lines in the second wiring group along the second direction D2. Different from the driving circuit structure 200, the first connection line 112 is connected to the clock signal line 103 not by means of the first via 105 but by means of welding at the welding region 117. Since the first connection line 112 spans the plurality of clock signal lines in the second wiring group along the second direction D2, the first connection line 112 can be welded to any clock signal line 103 in the second wiring group. Therefore, the selectivity of the location of the welding region 117 can be greatly increased, making the selection of the welding region 117 more flexible. Moreover, by adopting such an arrangement in which the first connection line 112 spans the plurality of clock signal lines in the second wiring group along the second direction D2, even in the case that some clock signal line 103 in the second wiring group has a fault such as disconnection, other clock signal lines 103 without fault in the second wiring group may be selected to be welded with the first connection line 102. Therefore, the connection reliability between the first connection line 112 and the clock signal line 103 can be greatly improved, and the production yield of the product can be improved.

Each clock signal line 103 in the second wiring group is connected to one end of a corresponding second connection line 113 through a group of third vias 114, and the other end of the second connection line 113 can be connected to the GOA unit.

Any clock signal line in the second wiring group has two cutting openings 115 and 116, and the first connection line 112 is welded to the clock signal line 103 having two cutting openings at the welding region 117. The clock signal line that is cut and welded in the second wiring group is the clock signal line that is selected to transmit the STV signal on the initial signal line 102, and the clock signal lines that are not cut and welded do not transmit the STV signal. Any one of the clock signal lines CLK1˜CLK12 can be selected to transmit the STV signal. FIG. 12 takes the clock signal line CLK3 as an example to transmit the STV signal. As illustrated in FIG. 12, the clock signal line CLK3 has two cutting openings 115 and 116, the first end 1121 of the first connection line 112 is connected to the initial signal line STV2 through the first via 105, and the first connection line 112 is welded to the clock signal line CLK3 in the welding region 117. The initial signal line STV2 is connected to the clock signal line CLK3 through the first via 105, the first connection line 112, and the welding region 117. The orthographic projection of the first connection line 112 on the base substrate 101 partially overlaps with the orthographic projection of the clock signal line CLK3 on the base substrate 101, and the overlapping region is the first orthographic projection. The clock signal line CLK3 is connected to the second connection line 113 through a group of third vias 114, and the second orthographic projection of the group of third vias 114 on the base substrate 101 falls within the orthographic projection of the clock signal line CLK3 on the base substrate 101. The first orthographic projection and the second orthographic projection need to be located between the orthographic projections of the two cutting openings 115 and 116 on the base substrate 101 to form an effective transmission path for the STV signal. For example, the clock signal line CLK3 is selected to transmit the STV signal, the effective transmission path of the STV signal is: the STV signal on the initial signal line STV2 is transmitted to the clock signal line CLK3 through the first connection line 112, and the clock signal line CLK3 transmits the STV signal to the GOA unit through the second connection line 113.

As illustrated in FIG. 12, the driving circuit structure 300 may also comprise a first power signal line 110 (or referred to as a VDDO wiring), a second power signal line 111 (or referred to as a VDDE wiring), a common electrode line COM, a third power signal line LVGL that are extending along the first direction D1. The display region of the display panel may be located on a side of the third power signal line L VGL away from the second wiring group. The first power signal line 110 and the second power signal line 111 are located on the side of the second wiring group away from the first wiring group, and the orthographic projections of the cutting openings 115 and 116 of the clock signal line and the welding region 117 on the base substrate 101 do not overlap with the orthographic projections of the first power signal line 110 and the second power signal line 111 on the base substrate 101. As mentioned before, in the related art, the distance between the initial signal line and the first and second power signal lines is very small, when the initial signal line and the clock signal line are welded, it is easy to cause a short circuit between the initial signal line and the nearby first and second power signal lines, thereby causing an abnormal display of the display panel. In contrast, in the driving circuit structure 300 of the embodiment of the present disclosure, the first power signal line 110 and the second power signal line 111 are designed to be away from the initial signal line 102, and the cutting openings 115 and 116 of the clock signal line 103 and the welding region 117 do not overlap with the first power signal line 110 and the second power signal line 111. In this way, even if the STV signal is introduced into the GOA unit by cutting and welding the clock signal line 103, it will not cause a short circuit between the initial signal line 102 and the first power signal line 110 and the second power signal line 111.

As illustrated in FIG. 12, in order to reduce resistance, the initial signal line 102 and the clock signal line 103 are designed to comprise hollow portions and solid portions. The orthographic projection of the first connection line 112 on the base substrate 101 may partially overlap with the orthographic projection of the solid portion of the clock signal line 103 on the base substrate 101, but the orthographic projections of the first connection line 112 and the first via 105 on the base substrate 101 do not overlap with the orthographic projection of the hollow portion of the clock signal line 103 on the base substrate 101, that is, the hollow portion of the clock signal line 103 is avoided. Since the first connection line 112 and the clock signal line 103 are located in different layers, by making the first connection line 112 and the first via 105 avoid the hollow portion of the clock signal line 103, the disconnection problem that occurs when the first connection line 112 climbs over the clock signal line 103 with a certain thickness can be reduced or even avoided, thereby improving the success rate of connection between the clock signal line 103 and the first connection line 112.

In some embodiments, the orthographic projection of the first connection line 112 on the base substrate 101 does not overlap with the orthographic projection of the second connection line 113 on the base substrate 101, so that a short circuit between the first connection line 112 and the second connection line 113 can be avoided. For example, the orthographic projection of the first connection line 112 on the base substrate 101 does not overlap with the orthographic projection of the third via 114 on the base substrate 101.

Since the first connection line 112 is connected to the clock signal line 103 by welding, it is possible to avoid providing the first via 105 in the position of the first insulating layer 104 corresponding to the clock signal line 103. Furthermore, since the first via 105 is not provided at the position corresponding to the clock signal line 103, external water vapor will not corrode the clock signal line 103 and/or the first connection line 112, therefore, there is no need to provide a protective pad at the position corresponding to the first via 105.

The display panel comprising the above-mentioned driving circuit structure 300 may be a display panel of various appropriate types and various sizes. For example, the display panel comprising the above-mentioned driving circuit structure 300 may be a display panel with a strip shape, which may be installed on a subway for display, for example. In some embodiments, the display panel comprising the above-mentioned driving circuit structure 300 is a strip screen with a size of 58.5 inches. The existing 65-inch mask may be optimized and designed, for example, the pattern of the first connection line 112 is added to the existing 65-inch mask, and then the optimized 65-inch mask is used to prepare a 58.5-inch strip screen, so as to realize the sharing of the mask. The specific preparation method will be described later and will not be described here.

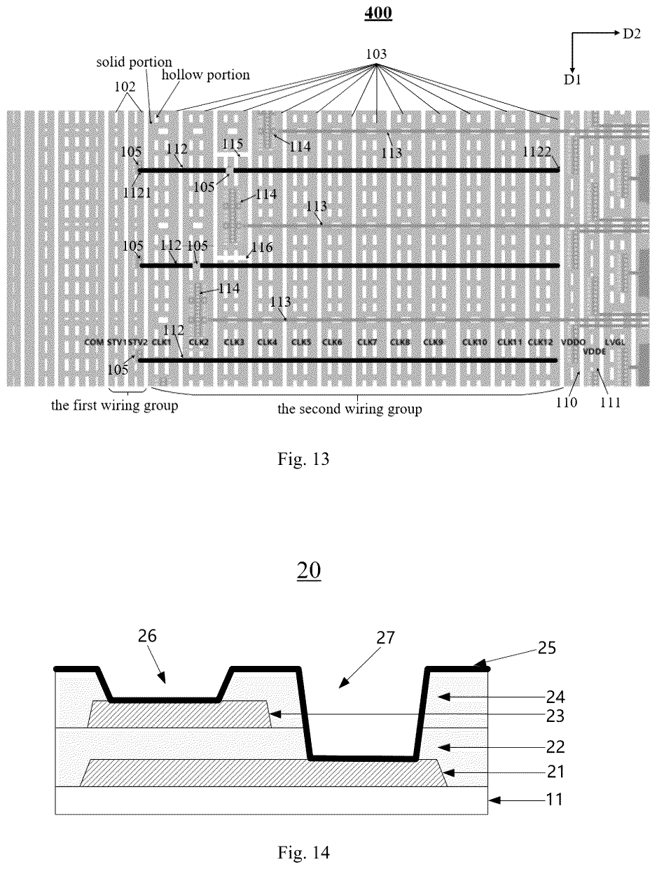

FIG. 13 provides a schematic layout of yet another driving circuit structure 400, which is a variant of the driving circuit structure 300. The driving circuit structure 400 illustrated in FIG. 13 has substantially the same construction as the driving circuit structure 300 illustrated in FIG. 12, and therefore the same reference numerals are used to refer to the same components. For the sake of simplicity, the similarities between the driving circuit structure 400 and the driving circuit structure 300 will not be repeatedly described, and only the differences will be introduced below.

Different from the driving circuit structure 300, in the driving circuit structure 400, the first connection line 112 is connected to the clock signal line 103 through the first via 105. Specifically, the first connection line 112 spans the plurality of clock signal lines 103 in the second wiring group along the second direction D2, and the first connection line 112 comprises a first end 1121 and a second end 1122 opposite to each other. The first end 1121 of the first connection line 112 is connected to any initial signal line 102 in the first wiring group through the first via 105, and the orthographic projection of the second end 1122 of the first connection line 112 on the base substrate 101 falls within the orthographic projection of a clock signal line 103 among the plurality of clock signal lines in the second wiring group on the base substrate 101 that is farthest from the initial signal line 102. Any clock signal line 103 in the second wiring group has two cutting openings 115 and 116, and the first connection line 112 is connected to the clock signal line 103 having two cutting openings through the first via 105.

In the driving circuit structure 400, the initial signal line 102 is connected to the first connection line 112 through the first via 105, and the first connection line 112 is connected to the clock signal line 103 through the first via 105. That is, the initial signal line 102 is connected to the clock signal line 103 through the first via 105 and the first connection line 112, thereby avoiding welding of the initial signal line 102 and the clock signal line 103. Therefore, in the driving circuit structure 400, the clock signal line 103 only needs to be cut but does not need to be welded, so that the STV signal can be introduced into the GOA unit through the clock signal line 103 to realize GOA driving.

For other technical effects of the driving circuit structure 400, reference may be made to the technical effects of the driving circuit structure 300. For the sake of simplicity, the technical effects of the driving circuit structure 400 will not be described again here.

FIG. 14 provides a schematic structural diagram of a partial region of a conventional array substrate 20. As illustrated in FIG. 14, the array substrate 20 comprises: a base substrate 11; a first conductive layer 21; a first insulating layer 22; a second conductive layer 23; a second insulating layer 24 comprising a via 26 and a via 27; and a third conductive layer 25. The second conductive layer 23 is connected to the third conductive layer 25 through the via 26, and the first conductive layer 21 is connected to the third conductive layer 25 through the via 27, that is, the second conductive layer 23 is connected to the first conductive layer 21 through the third conductive layer 25 (and the vias 26 and 27). The first conductive layer 21 may be an initial signal line, and the second conductive layer 23 may be a clock signal line.

The array substrate 20 mainly has the following two problems: on the one hand, the second conductive layer 23 must be connected to the first conductive layer 21 through the third conductive layer 25, however, the material of the third conductive layer 25 is usually different from the materials of the first conductive layer 21 and the second conductive layer 23, and the third conductive layer 25 has an area, this causes the third conductive layer 25 to have a large contact resistance, which is not conducive to meeting the electrical requirements of the array substrate 20; on the other hand, the second conductive layer 23 must be connected to the first conductive layer 21 through the vias 26 and 27, however, the depth of the via 27 is deep, during the process of etching the first insulating layer 22 and the second insulating layer 24 to form the via 27, due to the metal-induced plasma effect, the etching rate of the portions of the first insulating layer 22 and the second insulating layer 24 close to the second conductive layer 23 is generally greater than the etching rate of other portions, which is easy to cause the first insulating layer 22 below the second conductive layer 23 to be hollowed out, thereby forming an undercut. The existence of the undercut can easily cause other layers to break at the undercut, leading to problems such as abnormal connection and electrostatic breakdown.

An embodiment of the present disclosure provides an array substrate, which comprises the driving circuit structure described in any of the previous embodiments. The array substrate provided by the embodiment of the present disclosure can at least overcome the technical problems existing in the conventional array substrate 20.

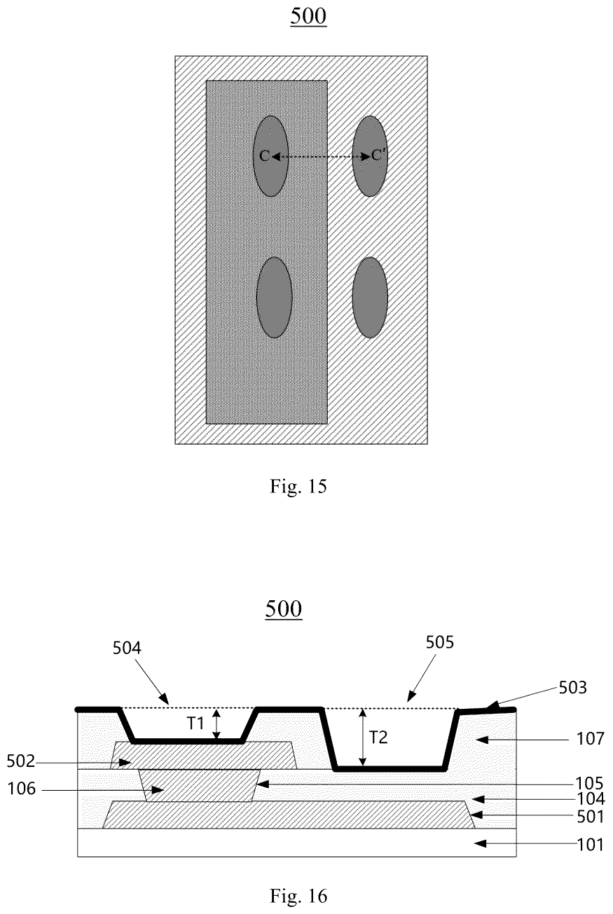

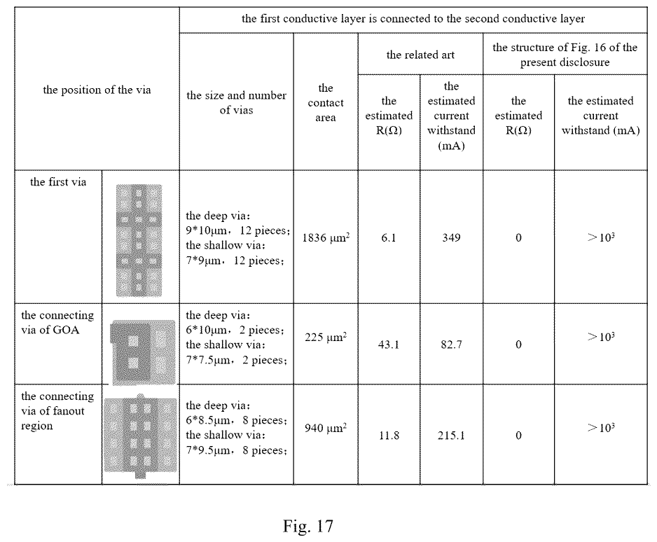

FIG. 15 illustrates a top view of a partial structure of an array substrate 500, and FIG. 16 illustrates a cross-sectional view taken along the line CC′ of FIG. 15. As illustrated in FIGS. 15 and 16, the array substrate 500 comprises: a base substrate 101; a first conductive layer 501 located on the base substrate 101, the first conductive layer 501 being located in the same layer as the initial signal line 102; a first insulating layer 104 comprising a first via 105; a second conductive layer 502 located on a side of the first insulating layer 104 away from the base substrate 101 and connected to the first conductive layer 501 through the conductor 106 in the first via 105; a second insulating layer 107 located on a side of the second conductive layer 502 away from the base substrate 101 and comprising a fourth via 504; and a third conductive layer 503 located on a side of the second insulating layer 107 away from the base substrate 101 and connected to the second conductive layer 502 through the fourth via 504.

FIGS. 15 and 16 illustrate a local region of the array substrate 500. The local region may be a GOA region of the array substrate 500, a fan-out region of the array substrate 500, or a display region of the array substrate 500. When the local region is the GOA region of the array substrate 500, the first conductive layer 501 may refer to the initial signal line 102, and the second conductive layer 502 may refer to the clock signal line 103, that is, this structure corresponds to the driving circuit structure 100; alternatively, the first conductive layer 501 may refer to the initial signal line 102 and/or the clock signal line 103, and the second conductive layer 502 may refer to the first connection line 112, that is, this structure corresponds to the driving circuit structures 200, 300, or 400. When the local region is the display region of the array substrate 500, the first conductive layer 501 may refer to the gate line and/or the gate electrode, the second conductive layer 502 may refer to the source and drain electrode, and the third conductive layer 503 may refer to the pixel electrode.

Different from the array substrate 20, in the array substrate 500, the first conductive layer 501 is connected to the second conductive layer 502 not by means of the third conductive layer 503, but by means of the conductor 106 in the first via 105. The second conductive layer 502 and the conductor 106 in the first via 105 are formed through the same patterning process, therefore, the conductor 106 in the first via 105 and the second conductive layer 502 are made of the same material. Therefore, the contact resistance of the conductor 106 in the first via 105 is negligible, that is, zero, which helps to improve the current withstand value of the array substrate 500. On the other hand, compared with the via 27 of the array substrate 20, the first via 105 of the array substrate 500 has a shallower depth. In the process of forming the first via 105, there is no undercut in the first insulating layer 104, thereby avoiding problems such as layer breakage, abnormal connection, and electrostatic breakdown, which helps to improve the reliability of the array substrate 500.

As illustrated in FIG. 16, in some embodiments, the second insulating layer 107 may also comprise a fifth via 505, the third conductive layer 503 fills the fourth via 504 and the fifth via 505, and the depth T2 of the fifth via 505 is greater than the depth T1 of the fourth via 504. In the product design stage, the size of the fourth via 504 may be smaller than the size of the fifth via 505, because during the actual preparation process, a shallower fourth via 504 is formed first, then a deeper fifth via 505 is formed. During the process of etching the fifth via 505, the fourth via 504 is inevitably continued to be etched, causing the size of the fourth via 504 to further increase. Therefore, in the design stage, the size of the fourth via 504 is designed to be smaller than the size of the fifth via 505, so as not to cause an excessive size difference between the fourth via 504 and the fifth via 505. On the premise of meeting the design rule, the larger the size of the fourth via 504 and the fifth via 505, the better the effect, because the fourth via 504 and the fifth via 505 are connected through the third conductive layer 503, the larger the size of the fourth via 504 and the fifth via 505, the larger the contact area of the third conductive layer 503, therefore the lower the resistance of the fourth via 504 and the fifth via 505 is and the better the current withstand of the product is, thereby avoiding the problem of static electricity caused by excessive via current.

FIG. 17 illustrates comparative data of contact resistance and current withstand value parameters of the conventional array substrate 20 and the array substrate 500 according to the embodiment of the present disclosure. In the via pattern of FIG. 17, the light-colored region refers to the first conductive layer, and the dark-colored region refers to the second conductive layer. The square in the light-colored region represents a deep via, and the square in the dark-colored region represents a shallow via. In the conventional array substrate 20, the first conductive layer 21 is connected to the second conductive layer 23 through the via 26 (the shallow via) and the via 27 (the deep via). In the array substrate 500, the first conductive layer 501 is connected to the second conductive layer 502 through the conductor 106 in the first via 105. It can be seen from the data in FIG. 17 that the conventional array substrate 20 has a larger resistance value and a smaller current withstand value at the via, while the array substrate 500 has a negligible resistance value (0Ω) and a larger current withstand value (>10³ mA) at the via.

In some alternative embodiments, the second insulating layer 107 may only comprise the fourth via 504 but not the fifth via 505, that is, the fifth via 505 is filled to be flat. In this way, there is no need to etch to form a deeper fifth via 505 during the preparation process, thereby reducing the etching time. The size of the fourth via 504 can be reduced, and the size of other vias in the display region formed by the same process as the fourth via 504 can also be reduced accordingly, which helps to increase the aperture ratio of the display region, improve the transmittance of the array substrate 500, and reduce the power consumption of the array substrate 500.

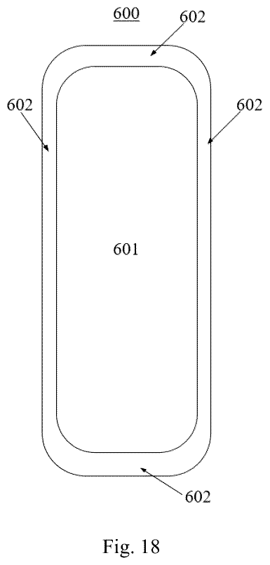

FIG. 18 illustrates a schematic structural diagram of a display device 600, which comprises the array substrate 500. The array substrate 500 may comprise the driving circuit structures 100, 200, 300, or 400 described in any of the previous embodiments. Example of the display device 600 comprises, but is not limited to, a mobile phone, a tablet computer, a television, a monitor, a notebook computer, a digital photo frame, and a navigator.

The display device 600 comprises a display region 601 and a peripheral region 602 arranged around the display region 601. The driving circuit structure 100, 200, 300, or 400 may be arranged at appropriate positions in the peripheral region 602. The driving circuit structure 100, 200, 300, or 400 may be a gate driving circuit structure, which may comprise multiple cascaded shift register circuits. The gate driving circuit structure may generate a plurality of gate driving signals transmitting to the gate lines, and may sequentially apply the plurality of gate driving signals to the respective gate lines. For example, the gate driving circuit structure may be integrated in the display device 600 as a gate driver on array (GOA) circuit.

For the technical effects of the display device 600, reference may be made to the technical effects of the driving circuit structure described in the previous embodiments. For the sake of brevity, the technical effects of the display device 600 will not be described again here.

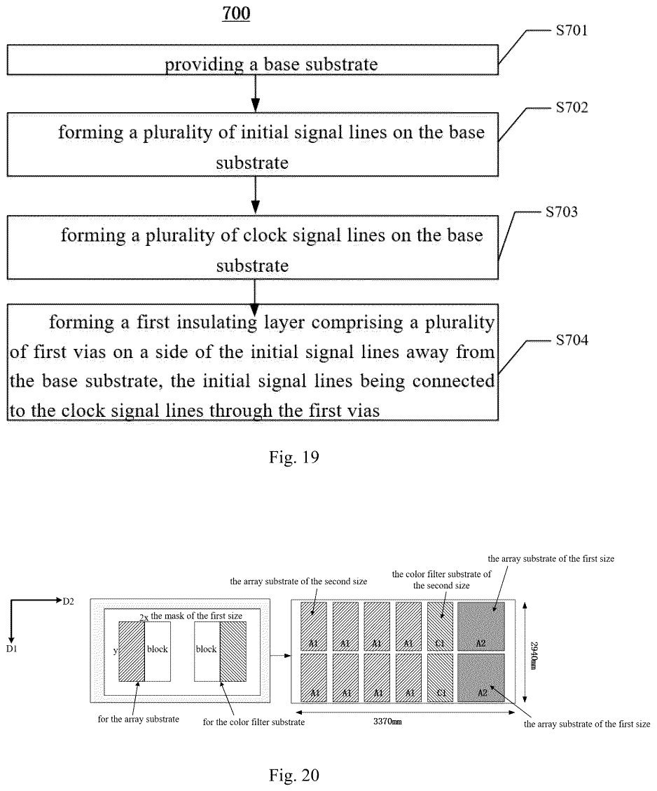

FIG. 19 illustrates a flow chart of a method 700 for preparing an array substrate. The array substrate may comprise the driving circuit structure described in any of the previous embodiments. Method 700 may comprise the following steps:
S701: providing a base substrate 101.
S702: forming a plurality of initial signal lines 102 on the base substrate 101.
S703: forming a plurality of clock signal lines 103 on the base substrate 101.
S704: forming a first insulating layer 104 comprising a plurality of first vias 105 on a side of the initial signal lines 102 away from the base substrate 101, the initial signal lines 102 being connected to the clock signal lines 103 through the first vias 105.

In the method 700, the initial signal line 102 is connected to the clock signal line 103 through the first via 105, so that the STV signal on the initial signal line 102 is introduced into the GOA unit through the clock signal line 103. In this way, a short circuit between the initial signal line 102 and other wirings can be avoided, which helps to improve the production yield of the array substrate.

First, the general flow of the preparation method of the conventional array substrate 20 may be described with reference to FIG. 14.

A base substrate 11 is provided.

Then, a first metal layer is deposited on the base substrate 11, and processes such as photoresist coating, exposure, development, etching, and photoresist stripping are performed on the metal layer by using a mask 1 to form a first conductive layer 21. The first conductive layer 21 may be an initial signal line, a gate line, a gate electrode, etc.

Then, a gate insulating layer, an amorphous silicon layer, an ohmic contact layer, and a second metal layer are sequentially deposited on the side of the first conductive layer 21 away from the base substrate 11, and processes such as photoresist coating, exposure, development, etching, and photoresist stripping are performed on the second metal layer by using a mask 2 to form a first insulating layer 22 and a second conductive layer 23. The second conductive layer 23 comprises, for example, a clock signal line, a first power signal line, a second power signal line, source and drain electrodes, and the like.

Afterwards, an insulating layer is deposited on the side of the second conductive layer 23 away from the base substrate 11, and processes such as photoresist coating, exposure, development, etching, and photoresist stripping are performed on the insulating layer by using a mask 3 to form a second insulating layer 24. The second insulating layer 24 is formed with via patterns in the display region and the GOA region respectively, comprising vias 26 and 27, for example.

Finally, an electrode layer is deposited on the side of the second insulating layer 24 away from the base substrate 11, and processes such as photoresist coating, exposure, development, etching, and photoresist stripping are performed on the second insulating layer 24 by using a mask 4 to form a third conductive layer 25, which may include pixel electrodes in the display region and a connection layer in the GOA region. As shown in FIG. 14, there is no via between the first conductive layer 21 and the second conductive layer 23, and the first conductive layer 21 and the second conductive layer 23 are connected through the third conductive layer 25.

In some embodiments, the size of masks 1, 2, 3 and 4 is 65 inches. For example, the array substrate 20 may be applied to a 65-inch TV.

The above-mentioned masks 1, 2, 3 and 4 can be optimized and improved, and the array substrate provided by the embodiments of the present disclosure can be prepared through blocking exposure and partial exposure, so as to realize the sharing of mask. The size of the array substrate provided by the embodiments of the present disclosure is different from the size of the masks 1, 2, 3 and 4 as mentioned above. The size of the above-mentioned masks 1, 2, 3 and 4 is a first size, the size of the array substrate formed by the method 700 is a second size, and the first size is different from the second size. For example, the size of the above-mentioned masks 1, 2, 3 and 4 is 65 inches, the size of the array substrate formed by the method 700 is 58.5 inches, the array substrate can be formed into a strip display screen, which can be installed, for example, on subways for display. It should be noted that the term such as “the size of masks 1, 2, 3 and 4 is the first size” means that the length of the diagonal of masks 1, 2, 3 and 4 is the first size. Similarly, the term such as “the size of the array substrate is the second size” means that the length of the diagonal of the array substrate is the second size.

By optimizing and improving the existing mask, the existing mask can not only be used to prepare products of the first size, but also can be used to prepare products of the second size, which can improve the utilization of mask and reduce development costs. In addition, because layers of other size(s) can be prepared by optimizing the existing mask without redesigning and preparing a new mask, it can respond to customer needs for products of different sizes more quickly.

With reference to FIG. 20, it will be described in more detail how to prepare an array substrate of the second size by using an existing mask of the first size.

In the example of FIG. 20, the length of the existing mask along the first direction D1 is y inches, the width of the existing mask along the second direction D2 is 2× inches, and the length of diagonal of the existing mask is 65 inches which is the first size. The existing mask can be used to prepare some layer(s) of the array substrate, or can be used to prepare some layer(s) of the color filter substrate. Block a half of the existing mask along the second direction D2, so that its length along the first direction D1 is still y inches, its width along the second direction D2 becomes x inches and its diagonal length becomes 58.5 inches, thus, a mask of the second size is formed. On a substrate with a length of 2940 mm in the first direction D1 and a length of 3370 mm in the second direction D2, by blocking a half of the existing mask for exposure, ten substrates with a diagonal length of 58.5 inches can be formed, wherein the substrate A1 can be an array substrate of 58.5 inches, and the substrate C1 can be a color filter substrate of 58.5 inches; by using the existing mask for normal exposure, two substrates A2 with a diagonal length of 65 inches can be formed on the right side of the substrate. Therefore, on the substrate with a length of 2940 mm in the first direction D1 and a length of 3370 mm in the second direction D2, ten 58.5-inch strip-shaped substrates and two 65-inch non-strip-shaped substrates can be formed.

It should be noted that sharing a 65-inch mask to prepare a 58.5-inch strip screen is just an example of sharing mask to prepare a strip screen, the specific size of the strip screen can be determined according to customer needs and application scenarios. When strip screens of other sizes are needed, strip screens of corresponding sizes may also be obtained by blocking ⅓, ¼, etc. of the 65-inch mask. Alternatively, strip screens of other required sizes may also be obtained by partially blocking mask of other sizes.

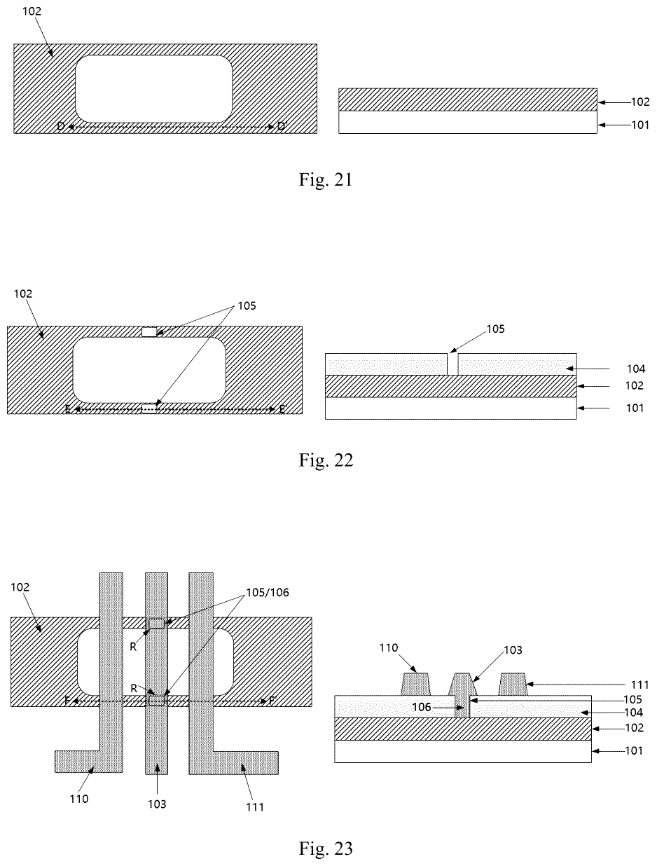

The method of preparing an array substrate comprising the driving circuit structure 100 will be described below with reference to FIGS. 21-25.

The left side of FIG. 21 is a top view, and the right side of FIG. 21 is a cross-sectional view taken along the line DD′ of the top view. As illustrated in FIG. 21, a base substrate 101 is first provided, the material of the base substrate 101 may be glass, for example. Then a first metal layer is deposited on the base substrate 101, and a portion of a first mask having the first size is blocked. Then, the first metal layer is patterned by performing processes such as photoresist coating, exposure, development, etching, and photoresist stripping to form multiple initial signal lines 102, gate lines, and the gate electrode. The first mask may be the aforementioned mask 1. The material of the first metal layer comprises but is not limited to molybdenum aluminum molybdenum (Mo/Al/Mo), molybdenum copper (Mo/Cu), molybdenum niobium copper (Mo/Nb/Cu), molybdenum niobium copper molybdenum titanium (Mo/Nb/Cu/Mo/Ti).

The left side of FIG. 22 is a top view, and the right side of FIG. 22 is a cross-sectional view taken along the line EE′ of the top view. As illustrated in FIG. 22, a gate insulating layer, an amorphous silicon layer, and an ohmic contact layer are sequentially deposited on the side of the initial signal line 102 away from the base substrate 101, and a portion of a second mask having the first size is blocked. Then, processes such as photoresist coating, exposure, development, etching, and photoresist stripping are performed to form the first insulating layer 104 and a plurality of first vias 105 penetrating the first insulating layer 104. The first via 105 exposes a portion of the surface of the initial signal line 102. The position of the first via 105 is the position where the initial signal line 102 and the clock signal line 103 overlap. The second mask can be obtained by adding the design pattern of the first via 105 to the aforementioned mask 3 at the position where the initial signal line 102 and the clock signal line 103 overlap.

Compared with FIG. 14, the method provided by the embodiment of the present disclosure adds a mask process for separately preparing the first insulating layer 104. In FIG. 14, the first insulating layer 22 has no via at the position corresponding to the second conductive layer 23, and the first insulating layer 22 and the second conductive layer 23 are formed by using a common mask. However, in FIG. 22, the first insulating layer 104 comprises the first via 105 at the position corresponding to the clock signal line 103, the first intermediate insulating layer needs to be patterned, therefore, a separate mask process is required to prepare the first insulating layer 104.

The left side of FIG. 23 is a top view, and the right side of FIG. 23 is a cross-sectional view taken along the line FF′ of the top view. As illustrated in FIG. 23, a second metal layer is deposited on the side of the first insulating layer 104 away from the base substrate 101, and a portion of a third mask having the first size is blocked. Then, the second metal layer is patterned by performing processes such as photoresist coating, exposure, development, etching, and photoresist stripping, to form the plurality of clock signal lines 103, the first power signal line 110, the second power signal line 111, source and drain electrodes (not illustrated) on the side of the first insulating layer 104 away from the base substrate 101, and simultaneously to form the conductor 106 in the first via 105. The initial signal line 102 is connected to the clock signal line 103 through the conductor 106 in the first via 105. The third mask may be the aforementioned mask 2. In some embodiments, the material of the second metal layer comprises, but is not limited to, molybdenum aluminum molybdenum (Mo/Al/Mo), molybdenum copper (Mo/Cu), molybdenum niobium copper (Mo/Nb/Cu), molybdenum niobium copper molybdenum Titanium (Mo/Nb/Cu/Mo/Ti).

The initial signal line 102 is connected to the clock signal line 103 through the conductor 106 in the first via 105 instead of by welding, in this way, a short circuit between the initial signal line 102 and other surrounding wirings during the welding process can be avoided, so that the display panel comprising the driving circuit structure 100 can display normally. In addition, in FIG. 23, the initial signal line 102 is connected to the clock signal line 103 through the conductor 106 in the first via 105, the depth of the first via 105 is much smaller than the depth of the via 27 of the conventional array substrate 20. Therefore, during the process of etching the first intermediate insulating layer to form the first via 105, no undercut will be formed, thereby avoiding problems such as layer breakage, abnormal connection, and electrostatic breakdown. In addition, the existence of the first via 105 can improve the identification of maintenance points, helping to improve the efficiency of maintenance personnel and the success rate of maintenance. The design of the first via 105 enriches the product design rules and expands the utilization rate of the mask.

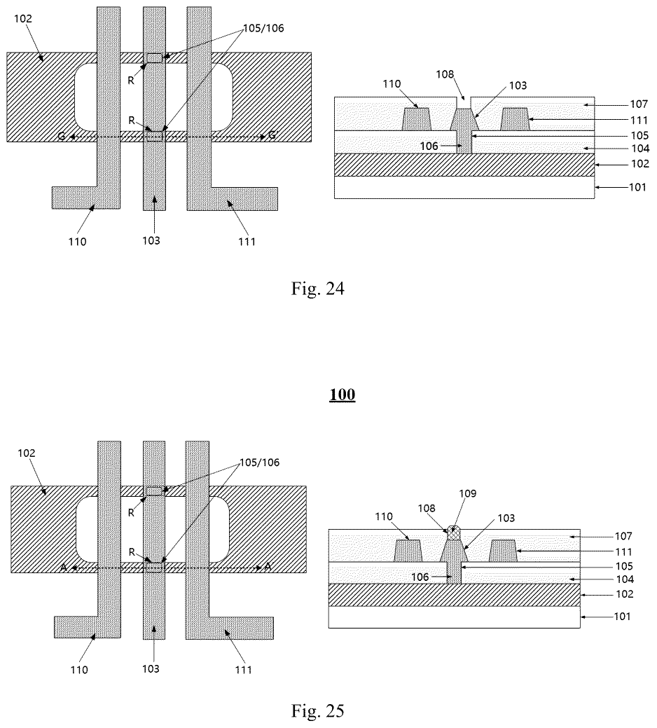

The left side of FIG. 24 is a top view, and the right side of FIG. 24 is a cross-sectional view taken along the line GG′ of the top view. As illustrated in FIG. 24, a second intermediate insulating layer is deposited on the side of the clock signal line 103 away from the base substrate 101, and a portion of the second mask having the first size is blocked. Then, processes such as photoresist coating, exposure, development, etching, and photoresist stripping are performed to form the second insulating layer 107. The second insulating layer 107 comprises a plurality of vias in the display region and a plurality of second vias 108 in the GOA region. The second via 108 exposes a portion of the surface of the clock signal line 103. The first insulating layer 104 and the second insulating layer 107 are formed by sharing the second mask.

The left side of FIG. 25 is a top view, and the right side of FIG. 25 is a cross-sectional view taken along the line AA′ of the top view. As illustrated in FIG. 25, a third metal layer is deposited on the side of the second insulating layer 107 away from the base substrate 101, and a portion of a fourth mask having the first size is blocked. Then, processes such as photoresist coating, exposure, development, etching, and photoresist stripping are performed to form the pixel electrode in the display region and the protective pad 109 in the GOA region. The protective pad 109 at least fills the second via 108. The protective pad 109 is mainly used to prevent the external water vapor from corroding the clock signal line 103 and the conductor 106. The fourth mask can be obtained by adding the pattern of the protective pad 109 to the aforementioned mask 4.

During preparing the array substrate comprising the driving circuit structure 100, The first, second, third and fourth masks can be obtained by optimizing and improving the structures of some of the aforementioned masks 1, 2, 3 and 4, for example, by adding the design pattern of the first via 105 to the mask 3 at a position corresponding to the clock signal line 103, and by adding the design pattern of the protective pad 109 to the mask 4. The array substrate of the second size can be prepared by shielding exposure and partial exposure of the first, second, third, and fourth masks having the first size, thereby realizing the sharing of the mask. In this way, the mask of the first size can not only be used to prepare the array substrate of the first size, but also be used to prepare the array substrate of the second size, thereby improving the utilization rate of the mask and saving product investment costs. In some embodiments, the first size may be 65 inches and the second size may be 58.5 inches. By blocking half of the mask of the first size for partial exposure, an array substrate of the second size may be obtained. The array substrate of the second size may be in a strip shape to form a strip display screen, which may be installed on a subway for display, for example.

The method of preparing an array substrate comprising the driving circuit structure 200 will be briefly described with reference to FIG. 9.

A base substrate 101 is provided. Then, a first metal layer is deposited on the base substrate 101, and the first metal layer is patterned by blocking a portion of the first mask having the first size to form the first wiring group, the second wiring group, gate lines, and the gate electrode. The first wiring group comprises a plurality of initial signal lines 102, and the second wiring group comprises a plurality of clock signal lines 103. The initial signal lines 102 and the clock signal lines 103 are arranged along the first direction and are located in the same layer. The orthographic projection of the initial signal line 102 on the base substrate 101 does not overlap with the orthographic projection of the clock signal line 103 on the base substrate 101. The first mask may be the aforementioned mask 1.

A first intermediate insulating layer is deposited on the side of the initial signal line 102 and the clock signal line 103 away from the base substrate 101, the first intermediate insulating layer is patterned by blocking a portion of the second mask having the first size to form the first insulating layer 104 comprising a plurality of first vias 105 and a plurality of groups of third vias 114. The first via 105 exposes a portion of the surface of the initial signal line 102 and the clock signal line 103, and the third via 114 exposes a portion of the surface of the clock signal line 103. The second mask may be obtained by adding the design pattern of the first via 105 to the aforementioned mask 3 at a position corresponding to the clock signal line 103.

A second metal layer is deposited on a side of the first insulating layer 104 away from the base substrate 101, and the second metal layer is patterned by blocking a portion of the third mask having the first size to form at least one first connection line 112 and at least one second connection line 113 arranged along the second direction D2, the first power signal line 110, the second power signal line 111, source and drain electrodes (not illustrated). The first connection line 112 comprises a first end 1121 and a second end 1122 opposite to each other. The first end 1121 of the first connection line 112 is connected to any initial signal line 102 in the first wiring group through the first via 105, and the second end 1122 of the first connection line 112 is connected to any clock signal line 103 in the second wiring group through the first via 105. Each clock signal line 103 in the second wiring group is connected to a corresponding second connection line 113 through a group of third vias 114. The third mask may be obtained by adding the design pattern of the first connection line 112 to the aforementioned mask 2.

A second intermediate insulating layer is deposited on the side of the first connection line 112 and the second connection line 113 away from the base substrate 101, the second intermediate insulating layer is patterned by blocking a portion of the second mask to form the second insulating layer 107 comprising a plurality of second vias 108. The first insulating layer 104 and the second insulating layer 107 may be formed by sharing the second mask.

A third metal layer is deposited on a side of the second insulating layer 107 away from the base substrate 101, and the third metal layer is patterned by blocking a portion of the fourth mask having the first size to form the pixel electrode in the display region and the protective pad 109 in the GOA region. The protective pad 109 at least fills the second via 108. The protective pad 109 mainly prevents the external water vapor from corroding the first connection line 112, the second connection line 113, and the conductive materials in the first via 105. The fourth mask may be obtained by adding the design pattern of the protective pad 109 to the aforementioned mask 4.

Any clock signal line 103 in the second wiring group is cut to make the clock signal line 103 have two cutting openings 115 and 116. The orthographic projection of the clock signal line 103 having the two cutting openings 115 and 116 on the base substrate 101 partially overlaps with the orthographic projection of the first connection line 112 connected to the clock signal line 103 on the base substrate 101 and the overlapping region is the first orthographic projection. The orthographic projection of a group of third vias 114 among the plurality of groups of third vias 114 on the base substrate 101 is the second orthographic projection. The second orthographic projection falls within the orthographic projection of the clock signal line 103 having the two cutting openings 115 and 116 on the base substrate 101. The first and second orthographic projections are located between the orthographic projections of the two cutting openings 115 and 116 on the base substrate 101. Cutting which clock signal line 103 means which clock signal line 103 is selected to transmit the STV signal on the initial signal line 102, and those clock signal lines 103 that are not cut do not transmit the STV signal. By positioning the two cutting openings 115 and 116 of the clock signal line 103 at the upper and lower sides of the first connection line 112 and the third via 114, an effective transmission path for the STV signal can be formed. In this embodiment, the initial signal line 102 is connected to the clock signal line 103 through the first via 105 and the first connection line 112, the clock signal line 103 only needs to be cut but does not need to weld with the first connection line 112, so that the STV signal can be transmitted through the clock signal line 103, which helps to improve the production efficiency.

During preparing the array substrate comprising the driving circuit structure 200, The first, second, third and fourth masks can be obtained by optimizing and improving the structures of some of the aforementioned masks 1, 2, 3 and 4, for example, by adding the design pattern of the first connection line 112 to the mask 2, by adding the design pattern of the first via 105 to the mask 3 at a position corresponding to the clock signal line 103, and by adding the design pattern of the protective pad 109 to the mask 4. The array substrate of the second size can be prepared by shielding exposure and partial exposure of the first, second, third, and fourth masks having the first size, thereby realizing the sharing of the mask. In this way, the mask of the first size can not only be used to prepare the array substrate of the first size, but also be used to prepare the array substrate of the second size, thereby improving the utilization rate of the mask and saving product investment costs. In some embodiments, the first size may be 65 inches and the second size may be 58.5 inches. By blocking half of the mask of the first size for partial exposure, an array substrate of the second size may be obtained. The array substrate of the second size may be in a strip shape to form a strip display screen, which may be installed on a subway for display, for example.

The method of preparing an array substrate comprising the driving circuit structure 300 will be briefly described with reference to FIG. 12.

A base substrate 101 is provided. Then, a first metal layer is deposited on the base substrate 101, and the first metal layer is patterned by blocking a portion of the first mask having the first size to form the first wiring group, the second wiring group, gate lines, and the gate electrode. The first wiring group comprises a plurality of initial signal lines 102, and the second wiring group comprises a plurality of clock signal lines 103. The initial signal lines 102 and the clock signal lines 103 are arranged along the first direction D1 and are located in the same layer. The orthographic projection of the initial signal line 102 on the base substrate 101 does not overlap with the orthographic projection of the clock signal line 103 on the base substrate 101. The first mask may be the aforementioned mask 1.

A first intermediate insulating layer and a second metal layer are sequentially deposited on the side of the initial signal line 102 and the clock signal line 103 away from the base substrate 101, the first intermediate insulating layer and the second metal layer are patterned by blocking a portion of the second mask having the first size to form the first insulating layer 104 comprising a plurality of first vias 105 and a plurality of groups of third vias 114, at least one first connection line 112 and at least one second connection line 113 arranged along the second direction D2, the first power signal line 110, the second power signal line 111, source/drain electrodes (not illustrated). Note that, unlike the driving circuit structure 200, in this embodiment, the first insulating layer 104 comprises the first via 105 only at the position corresponding to the initial signal line 102 but does not comprise the first via 105 at the position corresponding to the clock signal line 103. The first connection line 112 spans the plurality of clock signal lines 103 in the second wiring group along the second direction D2. The first connection line 112 comprises a first end 1121 and a second end 1122 opposite to each other, the first end 1121 of the first connection line 112 is connected to any initial signal line 102 in the first wiring group through the first via 105, the orthographic projection of the second end 1122 of the first connection line 112 on the base substrate 101 falls within the orthographic projection of a clock signal line 103 among the plurality of clock signal lines in the second wiring group on the base substrate 101 that is farthest from the initial signal line 102. The first connection line 112 spans multiple clock signal lines, thus multiple welding points can be provided, thereby greatly increasing the selectivity of welding locations. Each clock signal line 103 in the second wiring group is connected to one end of a corresponding second connection line 113 through a group of third vias 114, and the other end of the second connection line 113 is connected to the GOA unit.

In this embodiment, the first insulating layer 104 is not provided with the first via 105 at the position corresponding to the clock signal line 103. The structure of the first insulating layer 104 is the same as the structure of the first insulating layer 22 in the related art. Therefore, during preparing the driving circuit structure 300, the first insulating layer 104 may share the second mask with the first connection line 112 and the second connection line 113, and there is no need to add a separate mask process for the first insulating layer 104. The second mask may be obtained by adding the design pattern of the second connection line 112 to the aforementioned mask 2.

A second intermediate insulating layer is deposited on the side of the first connection line 112 and the second connection line 113 away from the base substrate 101, and the second intermediate insulating layer is patterned by blocking a portion of the third mask having the first size to form the second insulating layer 107. Since the first insulating layer 104 is not provided with the first via 105 at the position corresponding to the clock signal line 103, there is no need to provide a protective pad to protect the metal, and there is no need to form the second via 108 for accommodating the protective pad at a position of the second insulating layer 107 corresponding to the first via 105. The third mask may be the aforementioned mask 3.

A third metal layer is deposited on a side of the second insulating layer 107 away from the base substrate 101, and the third metal layer is patterned by blocking a portion of the fourth mask having the first size to form pixel electrodes in the display region. As mentioned above, since there is no need to provide a protective pad, there is no need to form a protective pad in the GOA region, and only the pixel electrodes need to be formed in the display region. The fourth mask may be the aforementioned mask 4.

Any clock signal line 103 in the second wiring group is cut to make the clock signal line 103 have two cutting openings 115 and 116, and the clock signal line 103 having the two cutting openings 115 and 116 is welded to the first connection line 112 located between the two cutting openings 115 and 116 at the welding point 117. The orthographic projection of the clock signal line 103 having the two cutting openings 115 and 116 on the base substrate 101 partially overlaps with the orthographic projection of the first connection line 112 welded to the clock signal line 103 on the base substrate 101, and the overlapping region is the first orthographic projection. The orthographic projection of one group of third vias 114 among the plurality of groups of third vias 114 on the base substrate 101 is the second orthographic projection. The second orthographic projection falls within the orthographic projection of the clock signal line 103 having the two cutting openings 115 and 116 on the base substrate 101, and the first and second orthographic projections are located between the orthographic projections of the two cutting openings 115 and 116 on the base substrate 101.

Cutting and welding which clock signal line 103 means which clock signal line 103 is selected to transmit the STV signal on the initial signal line 102, and those clock signal lines 103 that are not cut and welded do not transmit the STV signal. By positioning the two cutting openings 115 and 116 of the clock signal line 103 at the upper and lower sides of the first connection line 112 and the third via 114, an effective transmission path for the STV signal can be formed. In this embodiment, although the clock signal line 103 needs to be cut and welded to transmit the STV signal, the first power signal line 110 and the second power signal line 111 are designed to be far away from the initial signal line 102 and the cutting openings 115 and 116 of the clock signal line 103 and the welding region 117 do not overlap with the first power signal line 110 and the second power signal line 111, in this way, even if the STV signal is introduced into the GOA unit by cutting and welding the clock signal line 103, it will not cause a short circuit between the initial signal line 102 and the first power signal line 110 and the second power signal line 111.

In the process flow of preparing the array substrate comprising the driving circuit structure 300, it is only necessary to add the design pattern of the first connection line 112 to the mask 2, and there is no need to add the design pattern of the first via 105 to the mask 3 and the design pattern of the protective pad 109 to the mask 4, and there is no need to provide a separate mask process for the first insulating layer 104. Therefore, compared to the array substrate 20 of the related art, the process flow of the array substrate comprising the driving circuit structure 300 is basically the same as the process flow of the array substrate 20 except that the design pattern of the first connection line 112 needs to be added to the mask 2. By sharing the aforementioned masks 1, 3, and 4 of the first size and the improved mask 2, an array substrate of the second size can be prepared, thereby realizing the sharing of mask. In this way, the mask of the first size can not only be used to prepare the array substrate of the first size, but also be used to prepare the array substrate of the second size, thereby improving the utilization rate of the mask and saving product investment costs. In some embodiments, the first size may be 65 inches and the second size may be 58.5 inches. By blocking half of the mask of the first size for partial exposure, an array substrate of the second size may be obtained. The array substrate of the second size may be in a strip shape to form a strip display screen, which may be installed on a subway for display, for example.

It will be understood that although the terms first, second, third, etc. may be used herein to describe various elements, components, regions, layers and/or portions, these elements, components, regions, layers and/or portions should not be limited by these terms. These terms are only used to distinguish an element, component, region, layer or portion from another element, component, region, layer or portion. Thus, a first element, component, region, layer or portion discussed above could be termed a second element, component, region, layer or portion without departing from the teachings of the present disclosure.

Spatially relative terms such as “row”, “column”, “below”, “above”, “left”, “right”, etc. may be used herein for ease of description to describe factors such as the relationship of an element or feature to another element(s) or feature(s) illustrated in the figures. It will be understood that these spatially relative terms are intended to encompass different orientations of the device in use or operation in addition to the orientation depicted in the figures. For example, if the device in the figures is turned over, elements described as “below” other elements or features would then be oriented “above” other elements or features. Thus, the exemplary term “below” can encompass both an orientation of above and below. The device may be otherwise oriented (rotated 90 degrees or at other orientations) and the spatially relative descriptors used herein are interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to limit the present disclosure. As used herein, the singular forms “a,” “an,” and “the” are intended to comprise the plural forms as well, unless the context clearly dictates otherwise. It will be further understood that the terms “comprise” and/or “include” when used in this specification designate the presence of stated features, integers, steps, operations, elements and/or parts, but do not exclude the presence or addition of one or more other features, integers, steps, operations, elements, components and/or groups thereof. As used herein, the term “and/or” comprises any and all combinations of one or more of the associated listed items. In the description of this specification, description with reference to the terms “an embodiment,” “another embodiment,” etc. means that a particular feature, structure, material, or characteristic described in connection with the embodiment is included in at least one embodiment of the present disclosure. In this specification, schematic representations of the above terms are not necessarily directed to the same embodiment or example. Furthermore, the particular features, structures, materials or characteristics described may be combined in any suitable manner in any one or more embodiments or examples. Furthermore, those skilled in the art may combine the different embodiments or examples as well as the features of the different embodiments or examples described in this specification without conflicting each other.

It will be understood that when an element or layer is referred to as being “on”, “connected to”, “coupled to”, or “adjacent to” another element or layer, it may be directly on, directly connected to, directly coupled to, or directly adjacent to another element or layer, or intervening elements or layers may be present. In contrast, when an element is referred to as being “directly on”, “directly connected to”, “directly coupled to”, “directly adjacent to” another element or layer, with no intervening elements or layers present. However, in no case should “on” or “directly on” be interpreted as requiring a layer to completely cover the layer below.

Embodiments of the disclosure are described herein with reference to schematic illustrations (and intermediate structures) of idealized embodiments of the disclosure. As such, variations to the shapes of the illustrations are to be expected, e.g., as a result of manufacturing techniques and/or tolerances. Accordingly, embodiments of the present disclosure should not be construed as limited to the particular shapes of the regions illustrated herein, but are to comprise deviations in shapes due, for example, to manufacturing. Thus, the regions illustrated in the figures are schematic in nature and their shapes are not intended to illustrate the actual shape of a region of a device and are not intended to limit the scope of the present disclosure.

Unless otherwise defined, all terms (comprising technical and scientific terms) used herein have the same meaning as commonly understood by one of ordinary skill in the art to which this disclosure belongs. It will be further understood that terms such as those defined in commonly used dictionaries should be construed to have meanings consistent with their meanings in the relevant art and/or the context of this specification, and will not be idealized or overly interpreted in a formal sense, unless expressly defined as such herein.

As will be appreciated by those skilled in the art, although the steps of the methods of the present disclosure are depicted in a particular order in the figures, this does not require or imply that the steps must be performed in that particular order, unless the context clearly dictates otherwise. Additionally or alternatively, multiple steps may be combined into one step for execution, and/or one step may be decomposed into multiple steps for execution. Furthermore, other method steps may be inserted between the steps. The inserted steps may represent such as improvements of a method described herein, or may be unrelated to the method. Also, a given step may not be fully complete before the next step starts.

Although the foregoing discussion comprises several specific implementation details, these should not be interpreted as limitations on the scope of any invention or what may be claimed, but interpreted as descriptions of features of specific embodiments that may be limited to specific inventions. Specific features described in different embodiments in this specification may also be realized in combination in a single embodiment. On the contrary, different features described in a single embodiment may also be implemented separately or in any suitable sub-combination in multiple embodiments.

The above descriptions are merely specific embodiments of the present disclosure, but the protection scope of the present disclosure is not limited thereto. Any changes or substitutions that those skilled in the art can easily think of within the technical scope disclosed by the present disclosure, should be comprised within the protection scope of the present disclosure. Therefore, the protection scope of the present disclosure should be based on the protection scope of the claims.

1. A driving circuit structure comprising:
a base substrate;
an initial signal line on the base substrate;
a clock signal line on the base substrate; and
a first insulating layer on a side of the initial signal line away from the base substrate and comprising a first via,
wherein the initial signal line is connected to the clock signal line through the first via.

2. The driving circuit structure according to claim 1, further comprising:
a second insulating layer on a side of the first insulating layer away from the base substrate and comprising a second via; and
a protective pad at least partially filling at least the second via,
wherein an orthographic projection of the protective pad on the base substrate at least partially overlaps with an orthographic projection of the first via on the base substrate.

3. The driving circuit structure according to claim 1,
wherein the clock signal line is on the side of the initial signal line away from the base substrate, a conductor is in the first via, an end of the conductor is directly connected to the initial signal line, and another end of the conductor is directly connected to the clock signal line, and
wherein an orthographic projection of the initial signal line on the base substrate at least partially overlaps with an orthographic projection of the clock signal line on the base substrate to form an overlapping region, and an orthographic projection of the first via on the base substrate falls within the overlapping region.

4. (canceled)

5. The driving circuit structure according to claim 1, wherein the initial signal line and the clock signal line are in a same layer, and an orthographic projection of the initial signal line on the base substrate does not overlap with an orthographic projection of the clock signal line on the base substrate.

6. The driving circuit structure according to claim 5, further comprising:
a first wiring group comprising at least one initial signal line extending along a first direction;
a second wiring group comprising at least one clock signal line extending along the first direction, an orthographic projection of the second wiring group on the base substrate not overlapping with an orthographic projection of the first wiring group on the base substrate; and
at least one first connection line extending along a second direction intersecting with the first direction and on a side of the first insulating layer away from the base substrate,
wherein the at least one clock signal line in the second wiring group is connected to any one of the at least one initial signal line in the first wiring group through the first connection line.

7. The driving circuit structure according to claim 6, wherein the clock signal line comprises a hollow portion and a solid portion, an orthographic projection of the first connection line on the base substrate partially overlaps with an orthographic projection of the solid portion on the base substrate, and the orthographic projection of the first connection line and an orthographic projection of the first via on the base substrate do not overlap with an orthographic projection of the hollow portion on the base substrate.

8. The driving circuit structure according to claim 6, further comprising at least one second connection line extending along the second direction,
wherein the first insulating layer further comprises a plurality of groups of third vias, each clock signal line in the second wiring group is connected to a corresponding second connection line through a group of third vias among the plurality of groups of third vias, and an orthographic projection of the first connection line on the base substrate does not overlap with an orthographic projection of the second connection line on the base substrate.

9. (canceled)

10. The driving circuit structure according to claim 8, wherein a clock signal line in the second wiring group has two cutting openings,
wherein one of the at least one first connection line is connected to the clock signal line having the two cutting openings, an orthographic projection of the first connection line on the base substrate partially overlaps with an orthographic projection of the clock signal line having the two cutting openings on the base substrate to form a first orthographic projection, an orthographic projection of the group of third vias among the plurality of groups of third vias on the base substrate is a second orthographic projection, the second orthographic projection falls within the orthographic projection of the clock signal line having the two cutting openings on the base substrate, and the first orthographic projection and the second orthographic projection are between orthographic projections of the two cutting openings on the base substrate.

11. The driving circuit structure according to claim 10, wherein the first connection line comprises a first end and a second end opposite to each other, the first end of the first connection line is connected to any one of the at least one initial signal line in the first wiring group through the first via, and the second end of the first connection line is connected to the clock signal line in the second wiring group through the first via.

12. The driving circuit structure according to claim 10, wherein the second wiring group comprises a plurality of clock signal lines arranged in parallel along the first direction, the first connection line spans the plurality of clock signal lines in the second wiring group along the second direction, the first connection line comprises a first end and a second end opposite to each other, the first end of the first connection line is connected to any one of the at least one initial signal line in the first wiring group through the first via, and an orthographic projection of the second end of the first connection line on the base substrate falls within an orthographic projection of a clock signal line among the plurality of clock signal lines in the second wiring group on the base substrate that is farthest from the any one of the at least one initial signal line.

13. (canceled)

14. The driving circuit structure according to claim 12, further comprising a first power signal line and a second power signal line extending along the first direction,
wherein the one of the at least one first connection line is welded to the clock signal line having the two cutting openings, the first power signal line and the second power signal line are on a side of the second wiring group away from the first wiring group, and orthographic projections of the cutting openings of the clock signal line and an orthographic projection of a welding region on the base substrate do not overlap with orthographic projections of the first power signal line and the second power signal line on the base substrate; or
wherein the one of the at least one first connection line is connected to the clock signal line having the two cutting openings through the first via.

15. (canceled)

16. (canceled)

17. An array substrate comprising the driving circuit structure according to claim 1.

18. The array substrate according to claim 17, further comprising:
a first conductive layer in a same layer as the initial signal line;
a second conductive layer on a side of the first insulating layer away from the base substrate, the first conductive layer being connected to the second conductive layer through a conductor in the first via;
a second insulating layer on a side of the second conductive layer away from the base substrate and comprising a fourth via; and
a third conductive layer on a side of the second insulating layer away from the base substrate and connected to the second conductive layer through the fourth via.

19. The array substrate according to claim 18, wherein the second insulating layer further comprises a fifth via, the third conductive layer at least partially fills the fourth via and the fifth via, and a depth of the fifth via is greater than a depth of the fourth via.

20. A display device comprising the array substrate according to claim 17, wherein the display device comprises a display region and a peripheral region arranged around the display region, the driving circuit structure is arranged in the peripheral region.

21. (canceled)

22. A method of preparing an array substrate, comprising:
providing a base substrate;
forming a plurality of initial signal lines on the base substrate;
forming a plurality of clock signal lines on the base substrate; and
forming a first insulating layer comprising a plurality of first vias on a side of the initial signal lines away from the base substrate, the initial signal lines being connected to the clock signal lines through the first vias.

23. The method according to claim 22, wherein forming the initial signal lines, the clock signal lines, and the first insulating layer respectively by using different masks having a first size, so that the array substrate has a second size, the first size is larger than the second size, and the array substrate having the second size has a strip shape.

24. The method according to claim 23, wherein the forming the plurality of initial signal lines, the plurality of clock signal lines, and the first insulating layer on the base substrate, comprises:
depositing a first metal layer on the base substrate, patterning the first metal layer by blocking a portion of a first mask having the first size to form the plurality of initial signal lines;
depositing a first intermediate insulating layer on the side of the initial signal lines away from the base substrate, patterning the first intermediate insulating layer by blocking a portion of a second mask having the first size to form the first insulating layer comprising the plurality of first vias, the first vias exposing a portion of a surface of the initial signal lines;
depositing a second metal layer on a side of the first insulating layer away from the base substrate, patterning the second metal layer by blocking a portion of a third mask having the first size to simultaneously form the plurality of clock signal lines on the side of the first insulating layer away from the base substrate and a conductor in each of the first vias, one of the initial signal lines being connected to a respective one of the clock signal lines through the conductor;
depositing a second intermediate insulating layer on a side of the clock signal lines away from the base substrate, patterning the second intermediate insulating layer by blocking a portion of the second mask to form a second insulating layer comprising a plurality of second vias, the second vias exposing a portion of a surface of the clock signal lines; and
depositing a third metal layer on a side of the second insulating layer away from the base substrate, patterning the third metal layer by blocking a portion of a fourth mask having the first size to form a protective pad, the protective pad filling at least the second vias.

25. (canceled)

26. The method according to claim 23,
wherein the forming the plurality of initial signal lines and the plurality of clock signal lines on the base substrate, comprises: depositing a first metal layer on the base substrate, patterning the first metal layer by blocking a portion of a first mask having the first size to form a first wiring group and a second wiring group, the first wiring group comprising the plurality of initial signal lines arranged along a first direction, the second wiring group comprising the plurality of clock signal lines arranged along the first direction, an orthographic projection of the first wiring group on the base substrate not overlapping with an orthographic projection of the second wiring group on the base substrate,
wherein the method further comprises:
depositing a first intermediate insulating layer on the side of the initial signal lines and the clock signal lines away from the base substrate, patterning the first intermediate insulating layer by blocking a portion of a second mask having the first size to form the first insulating layer comprising the plurality of first vias and a plurality of groups of third vias, the first vias exposing a portion of surfaces of the initial signal lines and the clock signal lines, and the third vias exposing a portion of a surface of the clock signal lines;
depositing a second metal layer on a side of the first insulating layer away from the base substrate, patterning the second metal layer by blocking a portion of a third mask having the first size to form at least one first connection line and at least one second connection line arranged along a second direction, the first connection line comprising a first end and a second end opposite to each other, the first end of the first connection line being connected to any one of the initial signal lines in the first wiring group through the first vias, the second end of the first connection line being connected to any one of the clock signal lines in the second wiring group through the first vias, and each clock signal line in the second wiring group being connected to a corresponding second connection line through a group of third vias among the plurality of groups of third vias, the second direction intersecting with the first direction;
depositing a second intermediate insulating layer on a side of the first connection line and the second connection line away from the base substrate, patterning the second intermediate insulating layer by blocking a portion of the second mask to form a second insulating layer comprising a plurality of second vias;
depositing a third metal layer on a side of the second insulating layer away from the base substrate, patterning the third metal layer by blocking a portion of a fourth mask having the first size to form a protective pad, the protective pad filling at least the second vias; and
cutting a clock signal line in the second wiring group to make the clock signal line have two cutting openings,
wherein an orthographic projection of the first connection line connected to the clock signal line having the two cutting openings on the base substrate partially overlaps with an orthographic projection of the clock signal line having the two cutting openings on the base substrate to form a first orthographic projection, an orthographic projection of the group of third vias among the plurality of groups of third vias on the base substrate is a second orthographic projection, the second orthographic projection falls within the orthographic projection of the clock signal line having the two cutting openings on the base substrate, and the first orthographic projection and the second orthographic projection are between orthographic projections of the two cutting openings on the base substrate.

27. The method according to claim 23,
wherein the forming the plurality of initial signal lines and the plurality of clock signal lines on the base substrate, comprises: depositing a first metal layer on the base substrate, patterning the first metal layer by blocking a portion of a first mask having the first size to form a first wiring group and a second wiring group, the first wiring group comprising the plurality of initial signal lines arranged along a first direction, the second wiring group comprising the plurality of clock signal lines arranged along the first direction, an orthographic projection of the first wiring group on the base substrate not overlapping with an orthographic projection of the second wiring group on the base substrate,
wherein the method further comprises:
sequentially depositing a first intermediate insulating layer and a second metal layer on the side of the initial signal lines and the clock signal lines away from the base substrate, patterning the first intermediate insulating layer and the second metal layer by blocking a portion of a second mask having the first size to form the first insulating layer comprising the plurality of first vias and a plurality of groups of third vias as well as at least one first connection line and at least one second connection line arranged along a second direction, wherein the first vias expose a portion of a surface of the initial signal lines, and the third vias expose a portion of a surface of the clock signal lines, the first connection line spans the plurality of clock signal lines in the second wiring group along the second direction, the first connection line comprises a first end and a second end opposite to each other, the first end of the first connection line is connected to any one of the initial signal lines in the first wiring group through the first vias, an orthographic projection of the second end of the first connection line on the base substrate falls within an orthographic projection of a clock signal line among the plurality of clock signal lines in the second wiring group on the base substrate that is farthest from the initial signal lines, and each clock signal line in the second wiring group is connected to a corresponding second connection line through a group of third vias among the plurality of groups of third vias, the second direction intersects with the first direction;
depositing a second intermediate insulating layer on a side of the first connection line and the second connection line away from the base substrate, patterning the second intermediate insulating layer by blocking a portion of a third mask having the first size to form a second insulating layer;
depositing a third metal layer on a side of the second insulating layer away from the base substrate, patterning the third metal layer by blocking a portion of a fourth mask having the first size to form a pixel electrode;
cutting a clock signal line in the second wiring group to make the clock signal line have two cutting openings; and
welding the clock signal line having the two cutting openings and the first connection line between the two cutting openings in a welding region,
wherein an orthographic projection of the welding region on the base substrate is a first orthographic projection, an orthographic projection of the group of third vias among the plurality of groups of third vias on the base substrate is a second orthographic projection, the second orthographic projection falls within an orthographic projection of the clock signal line having the two cutting openings on the base substrate, and the first orthographic projection and the second orthographic projection are between orthographic projections of the two cutting openings on the base substrate.
